(19) United States
(12) Patent Application Publication
(10) Pub. No.: US 2025/0294766 A1
(43) Pub. Date: Sep. 18, 2025

(54) MEMORY DEVICE

(71) Applicant: Kioxia Corporation, Tokyo (JP)

(72) Inventors: Hiroaki FUKUDA, Utsunomiya (JP); Daigo ICHINOSE, Nagoya (JP)

(73) Assignee: Kioxia Corporation, Tokyo (JP)

(21) Appl. No.: 18/829,633

(22) Filed: Sep. 10, 2024

(30) Foreign Application Priority Data
Mar. 12, 2024 (JP) 2024-038018

(51) Int. Cl. H10B 43/35; H10B 43/10

(52) U.S. Cl. CPC H10B 43/35; H10B 43/10

(57) ABSTRACT

A semiconductor memory device according to an embodiment includes a substrate, first conductive layers, memory pillars, and first and second pillars. The substrate includes first to third regions arranged in order in a first direction. The first conductive layers are arranged in a second direction. The memory pillars are provided in the first region. Each of the memory pillars has a portion crossing the first conductive layers and includes a stacked film. The first pillars are provided in the second and third regions. Each of the first pillars has a portion crossing at least one of the first conductive layers and has a configuration different from the memory pillar. The second pillars are provided in the second region. Each of the second pillars has a portion crossing at least one first conductive layer and includes the stacked film.

### CROSS-REFERENCE TO RELATED APPLICATION

This application is based upon and claims the benefit of priority from Japanese Patent Application No. 2024-038018, filed Mar. 12, 2024, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF DRAWINGS

FIG. 1 is a block diagram showing an example of an overall configuration of a memory system including a memory device according to a first embodiment.

FIG. 2 is a circuit diagram showing an example of a circuit configuration of a memory cell array included in the memory device according to the first embodiment.

FIG. 3 is a perspective view showing an example of an external appearance of the memory device according to the first embodiment.

FIG. 4 is a plan view showing an example of a planar layout of the memory cell array included in the memory device according to the first embodiment.

FIG. 5 is a plan view showing an example of a planar layout in a memory region of the memory cell array included in the memory device according to the first embodiment.

FIG. 6 is a cross-sectional view taken along line VI-VI of FIG. 5, showing an example of a cross-sectional structure in the memory region of the memory cell array included in the memory device according to the first embodiment.

FIG. 7 is a cross-sectional view taken along line VII-VII of FIG. 6, showing an example of a cross-sectional structure of a memory pillar included in the memory device according to the first embodiment.

FIG. 8 is a plan view showing an example of a planar layout in the vicinity of a boundary region of the memory cell array included in the memory device according to the first embodiment.

FIG. 9 is a cross-sectional view taken along line IX-IX of FIG. 8, showing an example of a cross-sectional structure in the vicinity of the boundary region of the memory cell array included in the memory device according to the first embodiment.

FIG. 10 is a cross-sectional view showing an example of a cross-sectional structure of the memory device according to the first embodiment.

FIG. 11 is a plan view showing an example of a planar layout in the manufacturing process of the memory cell array included in the memory device according to the first embodiment.

FIG. 12 is a cross-sectional view taken along line XII-XII of FIG. 11, showing an example of a cross-sectional structure in the manufacturing process of the memory cell array included in the memory device according to the first embodiment.

FIG. 13 is a plan view showing an example of a planar layout in the manufacturing process of the memory cell array included in the memory device according to the first embodiment.

FIG. 14 is a cross-sectional view taken along line XIV-XIV of FIG. 13, showing an example of a cross-sectional structure in the manufacturing process of the memory cell array included in the memory device according to the first embodiment.

FIG. 15 is a plan view showing an example of a planar layout in the manufacturing process of the memory cell array included in the memory device according to the first embodiment.

FIG. 16 is a cross-sectional view taken along line XVI-XVI of FIG. 15, showing an example of a cross-sectional structure in the manufacturing process of the memory cell array included in the memory device according to the first embodiment.

FIG. 17 is a plan view showing an example of a planar layout in the manufacturing process of the memory cell array included in the memory device according to the first embodiment.

FIG. 18 is a cross-sectional view taken along line XVIII-XVIII of FIG. 17, showing an example of a cross-sectional structure in the manufacturing process of the memory cell array included in the memory device according to the first embodiment.

FIG. 19 is a plan view showing an example of a planar layout in the manufacturing process of the memory cell array included in the memory device according to the first embodiment.

FIG. 20 is a cross-sectional view taken along line XX-XX of FIG. 19, showing an example of a cross-sectional structure in the manufacturing process of the memory cell array included in the memory device according to the first embodiment.

FIG. 21 is a plan view showing an example of a planar layout of a memory cell array according to a first comparative example.

FIG. 22 is a cross-sectional view taken along line XXII-XXII of FIG. 21, showing an example of a cross-sectional structure of the memory cell array according to the first comparative example.

FIG. 23 is a plan view showing an example of a planar layout of a memory cell array according to a second comparative example.

FIG. 24 is a cross-sectional view taken along line XXIV-XXIV of FIG. 23, showing an example of a cross-sectional structure of the memory cell array according to the second comparative example.

FIG. 25 is a cross-sectional view showing an example of a cross-sectional structure of a memory cell array included in a memory device according to a second embodiment.

FIG. 26 is a cross-sectional view showing an example of a cross-sectional structure in the vicinity of a boundary region of the memory cell array included in the memory device according to the second embodiment.

FIGS. 27 to 33 are cross-sectional views showing an example of cross-sectional structures in the manufacturing process of the memory cell array included in the memory device according to the second embodiment.

FIG. 34 is a plan view showing an example of a planar layout of a memory cell array according to a first modification.

FIG. 35 is a cross-sectional view taken along line XXXV-XXXV of FIG. 34, showing an example of a cross-sectional structure of the memory cell array according to the first modification.

FIG. 36 is a plan view showing an example of a planar layout of a memory cell array according to a second modification.

FIG. 37 is a cross-sectional view taken along line XXXVII-XXXVII of FIG. 36, showing an example of a cross-sectional structure of the memory cell array according to the second modification.

FIG. 38 is a cross-sectional view showing an example of a detailed cross-sectional structure of the vicinity of two bonding pads arranged to face each other.

FIG. 39 is a cross-sectional view showing an example of a detailed cross-sectional structure of a boundary portion between a first tier and a second tier included in a memory pillar included in the memory device according to the second embodiment.

FIG. 40 is a cross-sectional view showing an example of a cross-sectional structure of a memory cell array according to a third modification.

FIG. 41 is a cross-sectional view showing an example of a cross-sectional structure of a memory device according to a fourth modification.

### DETAILED DESCRIPTION

In general, according to one embodiment, a semiconductor memory device includes a substrate, a plurality of first conductive layers, a plurality of memory pillars, a plurality of first pillars, and a plurality of second pillars. The substrate includes a first region, a second region, and a third region arranged in order in a first direction. The plurality of first conductive layers are arranged in a second direction crossing the first direction above the substrate. The plurality of memory pillars are provided in the first region. Each of the memory pillars has a portion crossing the first conductive layers and includes a stacked film. The plurality of first pillars are provided in the second region and the third region. Each of the first pillars has a portion crossing at least one of the first conductive layers and has a configuration different from a configuration of each of the memory pillars. The plurality of second pillars are provided in the second region. Each of the second pillars has a portion crossing at least one first conductive layer among the first conductive layers and includes the stacked film.

Hereinbelow, embodiments are described with reference to the drawings. Each embodiment gives examples of a device and a method for embodying the technical idea of the invention. The drawings are schematic or conceptual ones. The dimensions, ratios, etc. of drawings are not necessarily the same as the actual ones. The illustration of the configuration is omitted as appropriate. The hatching added to the plan view is not necessarily related to the material or characteristics of the component. In the present specification, components having substantially the same function and configuration are marked with the same reference signs. The numerals, characters, etc. added to reference signs are referred to by the same reference signs, and are used to distinguish between similar elements.

### <1>First Embodiment

A memory device 1 according to a first embodiment has a structure in which memory cells are three-dimensionally stacked and a manufacturing method of bonding two semiconductor substrates together is used. Then, a pattern for assisting the opening of memory holes in an end portion and a pattern for maintaining the structure of stacked wiring lines in a hookup region are arranged to overlap in a boundary region. Details of the memory device 1 according to the first embodiment will now be described.

### <1-1> Configuration

First, a configuration of the memory device 1 according to the first embodiment is described.

### <1-1-1>Overall Configuration of Memory Device 1

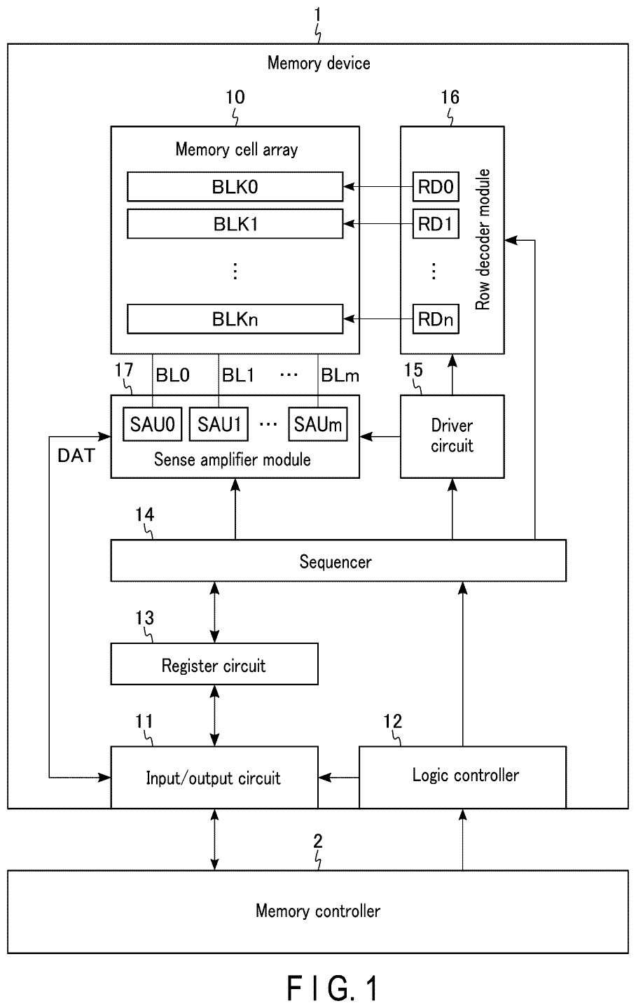

FIG. 1 is a block diagram showing an example of an overall configuration of a memory system including the memory device 1 according to the first embodiment. As shown in FIG. 1, the memory device 1 is controlled by a memory controller 2 in the outside. The memory device 1 is, for example, a NAND flash memory capable of storing data in a nonvolatile manner. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). The block BLK is a set of a plurality of memory cells. The block BLK corresponds to, for example, a unit of data erasure. The block BLK includes a plurality of pages. The page corresponds to a unit in which reading and writing of data are executed. Although illustration is omitted, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that takes charge of transmission and reception of input/output signals with the memory controller 2. The input/output signal includes, for example, data DAT, status information, address information, a command, etc. The input/output circuit 11 can input and output data DAT between the sense amplifier module 17 and the memory controller 2. The input/output circuit 11 can output, to the memory controller 2, status information transferred from the register circuit 13. The input/output circuit 11 can output, to the register circuit 13, each of address information and a command transferred from the memory controller 2.

The logic controller 12 controls each of the input/output circuit 11 and the sequencer 14 based on a control signal inputted from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 orders the input/output circuit 11 to input or output an input/output signal.

The register circuit 13 temporarily stores status information, address information, and a command. The status information is updated based on the control of the sequencer 14, and is transferred to the input/output circuit 11. The address information includes a block address, a page address, a column address, and the like. The command includes orders regarding various operations of the memory device 1.

The sequencer 14 controls the entire operation of the memory device 1. The sequencer 14 executes a read operation, a write operation, an erase operation, or the like based on a command and address information stored in the register circuit 13.

The driver circuit 15 generates voltage used in a read operation, a write operation, an erase operation, or the like. Then, the driver circuit 15 supplies the generated voltage to the row decoder module 16, the sense amplifier module 17, or the like.

The row decoder module 16 is a circuit used to select a block BLK to be operated and transfer voltage to a wiring line such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers voltage generated by the driver circuit 15 to various wiring lines provided in the memory cell array 10.

The sense amplifier module 17 is a circuit used to transfer voltage to each bit line BL and read data. The sense amplifier module 17 includes a plurality of sense amplifier units SAU0 to SAUm. The sense amplifier units SAU0 to SAUm are associated with the bit lines BL0 to BLm, respectively. Each sense amplifier unit SAU includes a sense amplifier capable of determining data based on the voltage of the associated bit line BL, a latch circuit that temporarily holds data, etc.

A combination of the memory device 1 and the memory controller 2 may constitute one semiconductor device. Examples of such a semiconductor device include a memory card such as an SD™ card, an SSD (solid-state drive), and the like.

### <1-1-2>Circuit Configuration of Memory Cell Array 10

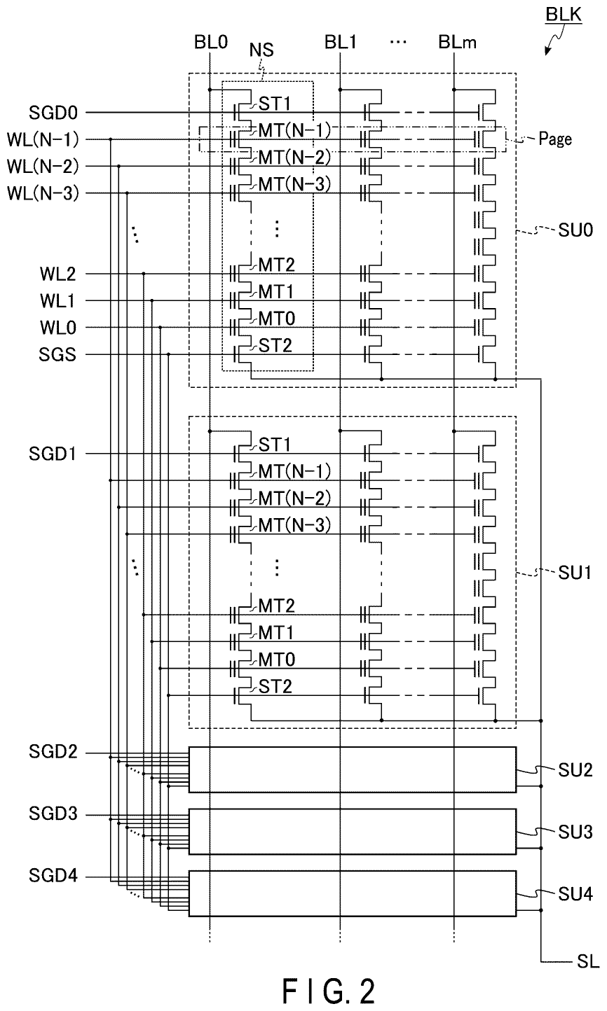

FIG. 2 is a circuit diagram showing an example of a circuit configuration of the memory cell array 10 included in the memory device 1 according to the first embodiment. FIG. 2 shows one block BLK among the blocks BLK included in the memory cell array 10. As shown in FIG. 2, select gate lines SGD0 to SGD4, word lines WL0 to WL (N-1) (N is an integer of 2 or more), a select gate line SGS, bit lines BL0 to BLm, and a source line SL are connected to the block BLK. Each of the set of select gate lines SGD0 to SGD4, the set of word lines WL0 to WL (N-1), and the select gate line SGS is provided on a block BLK basis. Each of the set of bit lines BL0 to BLm and the source line SL can be shared by a plurality of blocks BLK.

The block BLK includes, for example, five string units SU0 to SU4. Each string unit SU includes NAND strings NS0 to NSm. The NAND strings NS0 to NSm are associated with the bit lines BL0 to BLm, respectively. Each NAND string NS is connected between the associated bit line BL and the source line SL. Each bit line BL is shared by NAND strings NS to which the same column address is allocated among a plurality of blocks BLK.

Each NAND string NS includes, for example, a select transistor ST1, N memory cell transistors MT0 to MT (N-1), and a select transistor ST2. In each NAND string NS, the select transistor ST1, the memory cell transistors MT (N-1) to MT0, and the select transistor ST2 are connected in series in this order. The drain of the select transistor ST1 is connected to the associated bit line BL, and the source of the select transistor ST2 is connected to the source line SL. Each memory cell transistor MT includes a control gate and a charge storage layer, and holds (stores) data in a nonvolatile manner. The select transistors ST1 and ST2 are used to select the string unit SU.

The select gate lines SGD0 to SGD4 are associated with the string units SU0 to SU4, respectively. Each select gate line SGD is connected to the gate of each of the select transistors ST1 included in the associated string unit SU. The select gate line SGS is connected to the gate of each of the select transistors ST2 included in the block BLK. The word lines WL0 to WL (N-1) are connected to the control gates of the memory cell transistors MT0 to MT (N-1) included in the block BLK, respectively.

A set of memory cell transistors MT connected to a common word line WL in one string unit SU corresponds to a “page”. The set of memory cell transistors MT connected to a common word line WL in one string unit SU can have a storage capacity of two or more pages according to the number of bits stored in the memory cell transistors MT.

The memory cell array 10 may be another circuit configuration. For example, the number of string units SU included in the block BLK and the numbers of memory cell transistors MT and select transistors ST1 and ST2 included in the NAND string NS can be designed to arbitrary numbers. In the following, for the memory device 1 according to the first embodiment, a case where each NAND string NS includes eight memory cell transistors MT0 to MT7 connected to word lines WL0 to WL7, respectively, is described as an example.

### <1-1-3>Structure of Memory Device 1

A structure of the memory device 1 according to the first embodiment will now be described.

In the drawings referred to below, a three-dimensional orthogonal coordinate system is used. The X direction corresponds to the extending direction of the word line WL. The Y direction corresponds to the extending direction of the bit line BL. The Z direction corresponds to the vertical direction with respect to the front surface of a semiconductor substrate taken as a reference. The “up and down” is defined based on a direction along the Z direction. The positive direction (upward) corresponds to a direction away from the front surface side of a semiconductor substrate taken as a reference. The XY plane (cross section) corresponds to a plane (cross section) parallel to each of the X direction and the Y direction. The YZ cross section corresponds to a cross section parallel to each of the Y direction and the Z direction. The XZ cross section corresponds to a cross section parallel to each of the X direction and the Z direction. The “front surface of a semiconductor substrate” corresponds to a surface on a side on which a semiconductor circuit is formed. The “back surface of a semiconductor substrate” corresponds to a surface on the opposite side to the front surface of the semiconductor substrate.

### (1: External Appearance of Memory Device 1)

First, an external appearance of the memory device 1 according to the first embodiment is described. The memory device 1 according to the first embodiment is formed by a method in which two semiconductor circuit substrates each with a semiconductor circuit formed thereon are bonded together and the bonded semiconductor circuit substrates are separated on a chip basis. Specifically, the memory device 1 according to the first embodiment includes a structure formed by bonding semiconductor substrates W1 and W2 together. Each of the semiconductor substrates W1 and W2 is a silicon substrate. In the following, a case where the semiconductor substrate W2 is removed in the manufacturing process of the memory device 1 is described. Depending on the structure of the memory cell array 10, a part of the semiconductor substrate W2 may remain after the semiconductor substrates W1 and W2 are bonded together.

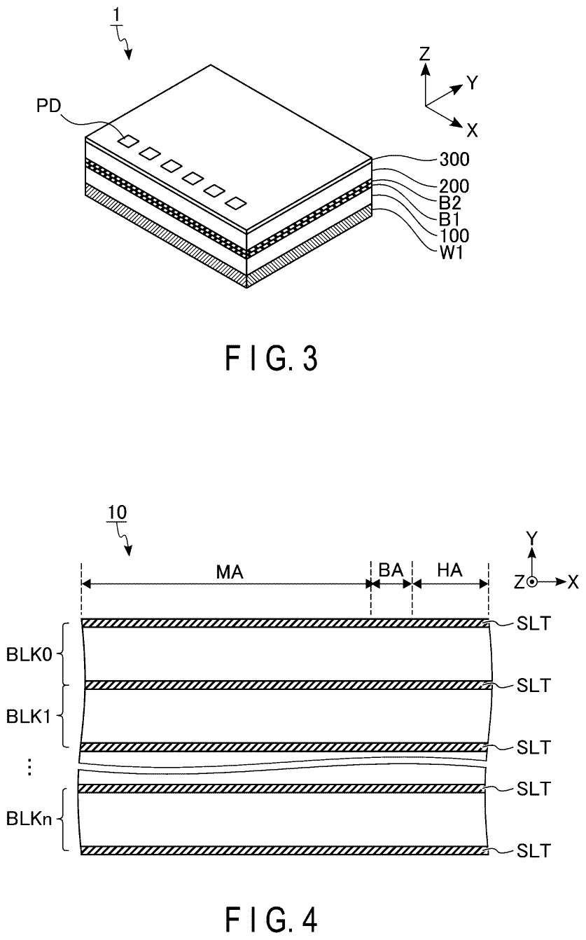

FIG. 3 is a perspective view showing an example of an external appearance of the memory device 1 according to the first embodiment. As shown in FIG. 3, the memory device 1 has a structure in which, for example, a semiconductor substrate W1, a CMOS layer 100, a bonding layer B1, a bonding layer B2, a memory layer 200, and a wiring layer 300 are stacked in this order from the bottom.

The CMOS layer 100 includes a CMOS circuit (control circuit) formed using the semiconductor substrate W1. The semiconductor substrate W1 has an impurity diffusion region, etc. according to the design of the CMOS circuit. The CMOS layer 100 includes, for example, control circuits such as the input/output circuit 11, the logic controller 12, the register circuit 13, the sequencer 14, the driver circuit 15, the row decoder module 16, and the sense amplifier module 17.

The bonding layer B1 is formed using the semiconductor substrate W1. The bonding layer B1 includes a plurality of bonding pads electrically connected to the CMOS circuit provided in the CMOS layer 100 and forming parts of the semiconductor circuit. The bonding layer B2 is formed using a semiconductor substrate W2 (not illustrated). The bonding layer B2 includes a plurality of bonding pads electrically connected to the memory cell array 10 provided in the memory layer 200 and forming parts of the semiconductor circuit. The bonding pads included in the bonding layer B1 are individually connected to the bonding pads BP included in the bonding layer B2. A portion between the bonding layers B1 and B2 corresponds to a boundary portion between a layer formed using the semiconductor substrate W1 and a layer formed using the semiconductor substrate W2 (not illustrated).

The memory layer 200 includes a memory cell array 10 formed using the semiconductor substrate W2. The wiring layer 300 is formed after the semiconductor substrates W1 and W2 are bonded together. The wiring layer 300 includes wiring lines connected to the semiconductor circuit provided in the memory layer 200 and a plurality of pads PD. The pads PD are exposed on a surface of the memory device 1. The pads PD are used for connection between the memory device 1 and the memory controller 2, etc.

### (2: Planar Layout of Memory Cell Array 10)

FIG. 4 is a plan view showing an example of a planar layout of the memory cell array 10 included in the memory device 1 according to the first embodiment. As shown in FIG. 4, the memory cell array 10 includes a plurality of slits SLT. Further, the memory cell array 10 has a memory region MA and a hookup region HA arranged in the X direction.

Each slit SLT corresponds to a plate-like member provided to extend along the X direction. Each slit SLT has a portion provided to extend along the X direction, and crosses the memory region MA and the hookup region HA along the X direction. The slits SLT are arranged in the Y direction. Each slit SLT divides wiring lines adjacent via the slit SLT (for example, the word lines WL0 to WL7 and the select gate lines SGD and SGS). In the memory cell array 10, each of the regions partitioned along the Y direction by the slits SLT corresponds to one block BLK.

The memory region MA is used to store data. The memory region MA includes a plurality of memory pillars configured to be able to store data. The hookup region HA is, for example, used for connection between stacked wiring lines (for example, the word lines WL0 to WL7 and the select gate lines SGD and SGS) and the row decoder module 16. The hookup region HA includes a plurality of support pillars for maintaining the structure of stacked wiring lines during formation of the stacked wiring lines. Hereinafter, a region sandwiched between the memory region MA and the hookup region HA is referred to as a boundary region BA. The boundary region BA includes a pattern for assisting the formation of memory pillars arranged in an end portion of the memory region MA.

### (3: Planar Layout in Memory Region MA of Memory Cell Array 10)

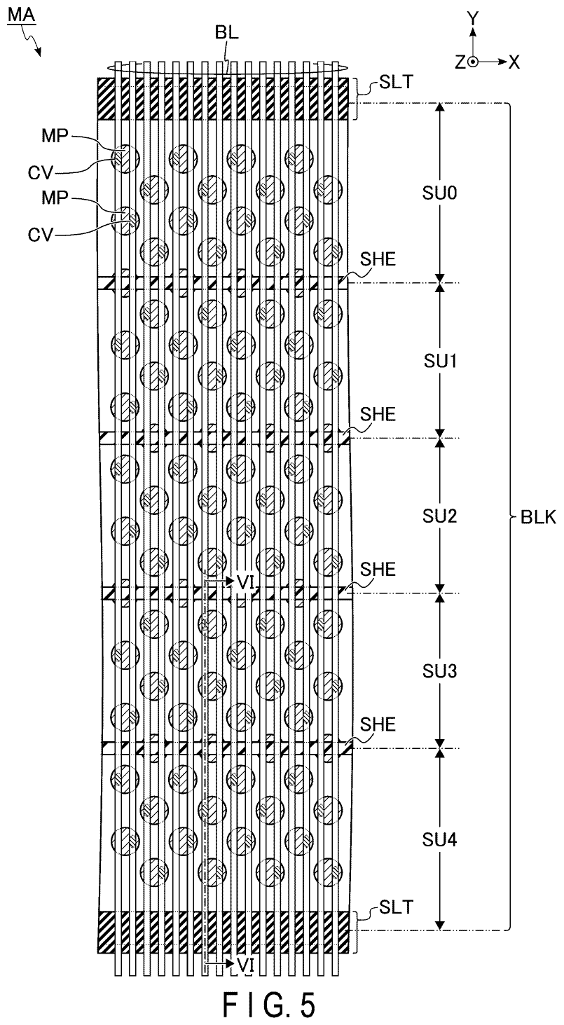

FIG. 5 is a plan view showing an example of a planar layout in the memory region of the memory cell array 10 included in the memory device 1 according to the first embodiment. FIG. 5 shows a region including one block BLK sandwiched between two adjacent slits SLT. As shown in FIG. 5, in the memory region MA, the memory device 1 includes, for example, a plurality of slits SHE, a plurality of memory pillars MP, a plurality of contacts CV, and a plurality of bit lines BL.

Each slit SHE has a portion provided to extend along the X direction, and crosses the memory region MA along the X direction. The slits SHE are arranged in the Y direction. In the present example, four slits SHE are arranged between two slits SLT adjacent in the Y direction. Each slit SHE has a structure in which, for example, an insulator is embedded. Each slit SHE divides wiring lines adjacent via the slit SHE (at least select gate lines SGD). In the memory cell array 10, each of the regions partitioned by the slits SLT and SHE corresponds to one string unit SU. In the present example, string units SU0 to SU4 are arranged between two adjacent slits SLT.

Each memory pillar MP is, for example, a columnar member corresponding to one NAND string NS. The memory pillars MP are arranged in a staggered configuration (lattice configuration) on a block BLK basis. For example, the memory pillars MP are arranged in a staggered configuration of 24 rows in a region between two adjacent slits SLT. In the present example, one slit SHE is provided to overlap with each of the 5th row of memory pillars MP, the 10th row of memory pillars MP, the 15th row of memory pillars MP, and the 20th row of memory pillars MP from the upper side of the paper surface.

Each bit line BL has a portion provided to extend in the Y direction. The bit lines BL are provided apart from the stacked wiring lines (for example, the word lines WL0 to WL7 and the select gate lines SGD and SGS) in the Z direction, and arranged in the X direction. Each bit line BL is provided to overlap with at least one memory pillar MP for each string unit SU. In the present example, two bit lines BL are arranged to overlap with one memory pillar MP. The memory pillar MP is electrically connected to, via a contact CV, one bit line BL among the bit lines BL arranged in an overlapping manner. A contact CV between a memory pillar MP in contact with two different select gate lines SGD and the bit line BL can be omitted.

The planar layout of the memory region MA may be another layout. For example, the numbers and arrangements of memory pillars MP, slits SHE, etc. arranged between two adjacent slits SLT can be changed as appropriate. The number of bit lines BL overlapping with each memory pillar MP can be designed to an arbitrary number.

### (4: Cross-sectional Structure in Memory Region MA of Memory Cell Array 10)

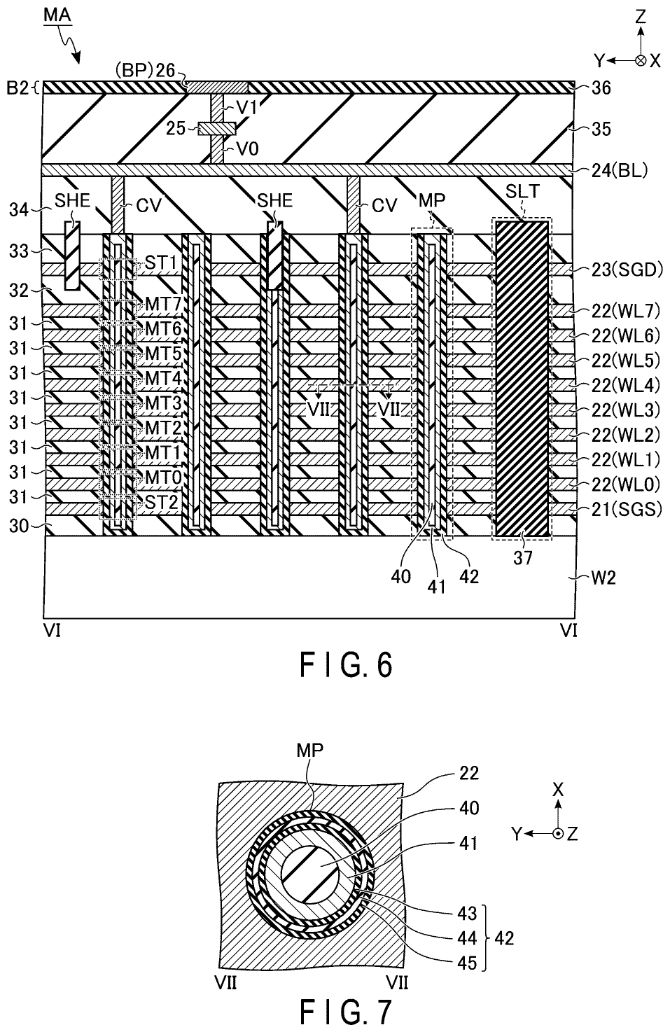

FIG. 6 is a cross-sectional view taken along line VI-VI of FIG. 5, showing an example of a cross-sectional structure in the memory region MA of the memory cell array 10 included in the memory device 1 according to the first embodiment. FIG. 6 shows an example of a structure of the memory cell array 10 formed on the semiconductor substrate W2 before being bonded to the semiconductor substrate W1, and shows coordinate axes with the semiconductor substrate W2 as a reference. As shown in FIG. 6, in the memory region MA, the memory cell array 10 includes, for example, conductive layers 21 to 26, insulating layers 30 to 36, an insulating member 37, and contacts V0 and V1.

An insulating layer 30 is provided on the semiconductor substrate W2. A conductive layer 21 is provided on the insulating layer 30. An insulating layer 31 and a conductive layer 22 are alternately provided on the conductive layer 21. An insulating layer 32, a conductive layer 23, an insulating layer 33, an insulating layer 34, and a conductive layer 24 are provided in this order on the uppermost conductive layer 22. Each of the conductive layers 21, 22, and 23 is, for example, formed in a plate shape spreading along the XY plane. The conductive layer 24 has, for example, a portion formed in a line shape extending in the Y direction. The conductive layer 21 is used as a select gate line SGS. The conductive layers 22 are used individually as word lines WL0 to WL7 in this order from the bottom. The conductive layer 23 is used as a select gate line SGD. The conductive layer 24 is used as a bit line BL.

A conductive layer 25 is provided above the conductive layer 24. The conductive layer 24 and the conductive layer 25 are connected via a contact V0. A conductive layer 26 is provided above the conductive layer 25. The conductive layer 25 and the conductive layer 26 are connected via a contact V1. The side surfaces of the conductive layer 25 and the contacts V0 and V1 are covered with an insulating layer 35. The insulating layer 35 can include a plurality of insulating films. The side surface of the conductive layer 26 is covered with an insulating layer 36. The insulating layer 36 and the conductive layer 26 are included in a bonding layer B2. The conductive layer 26 corresponds to a bonding pad BP. The conductive layer 26 contains, for example, copper.

A slit SLT divides the insulating layers 30 to 33 and the conductive layers 21 to 23. An insulating member 37, for example, is embedded in the slit SLT. The insulating member 37 has a portion formed in a plate shape spreading along the XZ plane. In the slit SLT, a conductor provided with a spacer of an insulator on its side wall may be provided to be insulated from these wiring lines.

Each memory pillar MP is provided to extend along the Z direction, and penetrates the insulating layers 30 to 33 and the conductive layers 21 to 23. Each memory pillar MP includes, for example, a core member 40, a semiconductor layer 41, and a stacked film 42. The core member 40 is an insulator provided to extend along the Z direction. The semiconductor layer 41 covers the core member 40. A lower portion of the semiconductor layer 41 is, for example, in contact with the semiconductor substrate W2. The stacked film 42 covers the side surface and the bottom surface of the semiconductor layer 41. The semiconductor layer 41 and the conductive layer 24 are connected via a contact CV.

A portion where the memory pillar MP and the conductive layer 21 cross each other functions as a select transistor ST2. A portion where the memory pillar MP and the conductive layer 22 cross each other functions as a memory cell transistor MT. A portion where the memory pillar MP and the conductive layer 23 cross each other functions as a select transistor ST1. In each memory pillar MP, the semiconductor layer 41 is used as channels (current paths) of the memory cell transistors MT0 to MT7 and the select transistors ST1 and ST2 included in a NAND string NS.

### (5: Cross-sectional Structure of Memory Pillar MP)

FIG. 7 is a cross-sectional view taken along line VII-VII of FIG. 6, showing an example of a cross-sectional structure of the memory pillar MP included in the memory device 1 according to the first embodiment. FIG. 7 shows a cross section including the memory pillar MP and the conductive layer 22 and parallel to the surface of the semiconductor substrate W2. As shown in FIG. 7, the stacked film 42 includes, for example, a tunnel insulating film 43, an insulating film 44, and a block insulating film 45. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 22 surrounds the side surface of the block insulating film 45. Each of the tunnel insulating film 43 and the block insulating film 45 contains, for example, silicon oxide (SiO₂). The insulating film 44 is used as a charge storage layer of the memory cell transistor MT. The insulating film 44 contains, for example, silicon nitride.

### (6: Planar Layout in Vicinity of Boundary Region BA of Memory Cell Array 10)

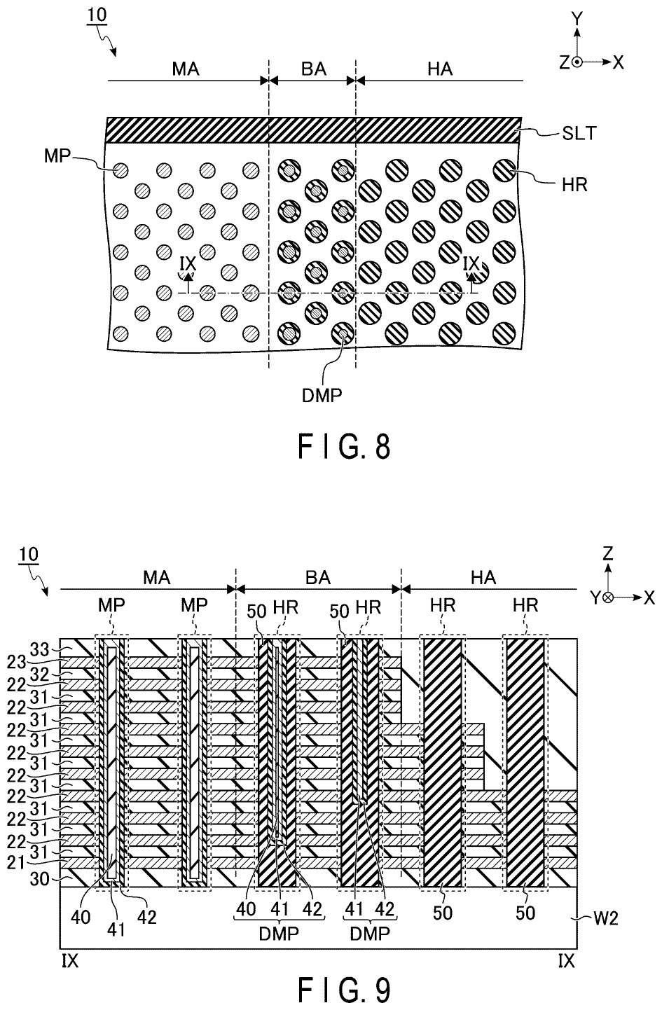

FIG. 8 is a plan view showing an example of a planar layout in the vicinity of the boundary region BA of the memory cell array 10 included in the memory device 1 according to the first embodiment. FIG. 8 shows the boundary region BA and parts of the memory region MA and the hookup region HA adjacent to the boundary region BA. As shown in FIG. 8, each of the hookup region HA and the boundary region BA includes a plurality of support pillars HR. The boundary region BA further includes a plurality of dummy pillars DMP.

Each support pillar HR is a columnar member for maintaining the structure of stacked wiring lines included in the memory cell array 10. At the same height, the diameter and the cross-sectional area of the support pillar HR are larger than the diameter and the cross-sectional area of the memory pillar MP respectively. The support pillars HR are arranged in a staggered configuration (lattice configuration) on a block BLK basis in each of the hookup region HA and the boundary region BA.

The dummy pillars DMP correspond to a pattern for assisting the formation of memory pillars MP arranged in an end portion of the memory region MA. At the same height, the diameter and the cross-sectional area of the dummy pillar DMP are smaller than the diameter and the cross-sectional area of the support pillar HR respectively. The diameter of the dummy pillar DMP has a tendency to, for example, decrease with proximity to the hookup region HA. Each dummy pillar DMP has the same layer structure as the memory pillar MP. Depending on the position, each dummy pillar DMP can have a structure in which a part of the configuration included in the memory pillar MP is omitted.

The dummy pillars DMP are arranged in a staggered configuration on a block BLK basis in the boundary region BA. In the boundary region BA and between two adjacent slits SLT, it is preferable that the numbers of rows and columns of support pillars HR arranged in a staggered configuration and the numbers of rows and columns of dummy pillars DMP arranged in a staggered configuration be designed to be the same, respectively. It is more preferable that the dummy pillars DMP provided in the boundary region BA completely overlap with the support pillars HR provided in the boundary region BA in the Z direction.

### (7: Cross-sectional Structure in Vicinity of Boundary Region BA of Memory Cell Array 10)

FIG. 9 is a cross-sectional view taken along line IX-IX of FIG. 8, showing an example of a cross-sectional structure in the vicinity of the boundary region BA of the memory cell array 10 included in the memory device 1 according to the first embodiment. FIG. 9 shows an example of a structure of the memory cell array 10 formed on the semiconductor substrate W2 before being bonded to the semiconductor substrate W1, and shows coordinate axes with the semiconductor substrate W2 as a reference. As shown in FIG. 9, in the hookup region HA and the boundary region BA, the memory cell array 10 includes a plurality of insulating members 50 individually corresponding to the support pillars HR.

Each insulating member 50 has a shape extending in the Z direction from the insulating layer 33 to the insulating layer 30. Each support pillar HR penetrates the insulating layers 30 and 33 and, among the insulating layers 31 and 32 and the conductive layers 21 to 23, at least some layers sandwiched between the insulating layer 33 and the insulating layer 30. A bottom portion of the insulating member 50 is in contact with the semiconductor substrate W2. The structure of each insulating member 50 is similar between the hookup region HA and the boundary region BA. The insulating member 50 contains, for example, silicon oxide (SiO₂). That is, the insulating member 50 contains, for example, oxygen and silicon. Thus, the configuration of the support pillar HR and the configuration of the memory pillar MP are different.

The upper surface of the dummy pillar DMP is aligned with the upper surface of the memory pillar MP. The upper surface of the dummy pillar DMP may or may not be aligned with the upper surface of the support pillar HR. The side surface and a bottom portion of each dummy pillar DMP are covered with the insulating member 50 (the support pillar HR) overlapping in the Z direction. Thus, the length in the Z direction of each dummy pillar DMP is shorter than the length in the Z direction of the support pillar HR. In the present example, a dummy pillar DMP provided on the memory region MA side has a similar layer structure (the core member 40, the semiconductor layer 41, and the stacked film 42) to the memory pillar MP. For example, the film thickness of the stacked film 42 included in the dummy pillar DMP and the film thickness of the stacked film 42 included in the memory pillar MP are substantially the same. Further, in the present example, a dummy pillar DMP provided on the hookup region HA side has only the semiconductor layer 41 and the stacked film 42 of the layer structure of the memory pillar MP due to the fact that the diameter and the cross-sectional area are smaller than those of a dummy pillar DMP on the memory region MA side respectively. A conductive layer (for example, the bit line BL) apart in the Z direction from the stacked wiring lines included in the memory cell array 10 is not connected to the dummy pillar DMP.

In the hookup region HA, each of the stacked wiring lines included in the memory cell array 10 can have a terrace portion. The terrace portion corresponds to a portion not overlapping with a wiring line (a conductive layer) on the upper side (the opposite side to the semiconductor substrate W2) in a top view. The structure formed by the terrace portions is similar to steps, terraces, rimstone, or the like. In the present example, only the terrace portions of two conductive layers 22 are illustrated. Further, in the present example, the level differences formed by the terrace portions are filled with the insulating layer 33. A contact (not illustrated) provided in the hookup region HA is connected to the terrace portion of the associated wiring line among the stacked wiring lines. The wiring line and the row decoder module 16 are electrically connected via the contact and a not-illustrated wiring line.

### (8: Cross-sectional Structure of Memory Device 1)

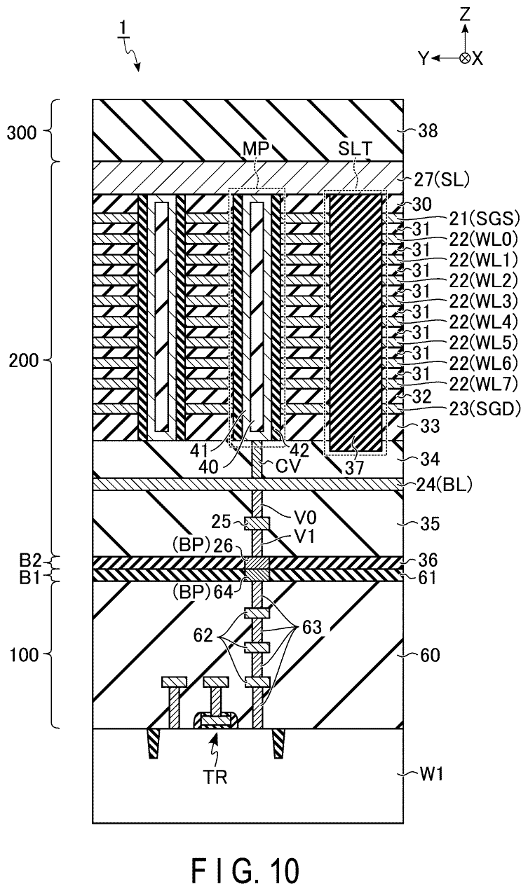

FIG. 10 is a cross-sectional view showing an example of a cross-sectional structure of the memory device 1 according to the first embodiment. FIG. 10 shows coordinate axes with the semiconductor substrate W1 as a reference. As shown in FIG. 10, the CMOS layer 100 includes an insulating layer 60, a plurality of conductive layers 62, and a plurality of contacts 63. The bonding layer B1 includes an insulating layer 61 and a conductive layer 64. The memory layer 200 includes insulating layers 30 to 36, conductive layers 21 to 27, a plurality of memory pillars MP, a slit SLT, and contacts CV, V0, and V1. The wiring layer 300 includes an insulating layer 38. A transistor TR is provided on the semiconductor substrate W1. The transistor TR corresponds to an element included in the sense amplifier module 17.

In the CMOS layer 100, the insulating layer 60 is provided on the semiconductor substrate W1. In the interior of the insulating layer 60, at least one contact 63 and at least one conductive layer 62 are connected in series on the transistor TR. The insulating layer 60 may include a plurality of insulating films. The insulating layer 61 is provided on the insulating layer 60. The conductive layer 64 is in contact with an upper portion of the uppermost contact 63 indirectly connected to the transistor TR. The conductive layer 64 corresponds to a bonding pad BP formed using the semiconductor substrate W1. The conductive layer 64 is in contact with the conductive layer 26 provided to face the conductive layer 64 in the Z direction.

The memory layer 200 includes a structure in which the structure in the memory region MA of the memory cell array 10 described using FIG. 6 is vertically inverted. In the present example, the semiconductor substrate W2 has been removed, and a part of the insulating layer 30, a part of the insulating member 37 in the slit SLT, and the stacked film 42 of an upper portion of the memory pillar MP have been removed. The conductive layer 27 is provided on the insulating layer 30. The conductive layer 27 is formed in a plate shape spreading along the XY plane. The conductive layer 27 is in contact with the semiconductor layer 41 of an upper portion of the memory pillar MP. The conductive layer 27 is used as a source line SL. The insulating layer 38 is provided on the conductive layer 27. The insulating layer 38 includes the pads PD described using FIG. 3, wiring lines for connecting the pads PD and the input/output circuit 11, etc. (not illustrated).

In the present example, although illustration is omitted, the height of the upper surface of the support pillar HR is aligned with the upper surface of the memory pillar MP by the process of removing the semiconductor substrate W2 and the stacked film 42 of an upper portion of the memory pillar MP. Further, although illustration is omitted, an upper portion of the support pillar HR may be in contact with the conductive layer 27 (the source line SL) similarly to the memory pillar MP, or may be in contact with a not-illustrated insulating layer. The number of wiring layers included in the memory device 1 is not limited to the number of wiring layers shown in FIG. 10.

### <1-2>Manufacturing Method

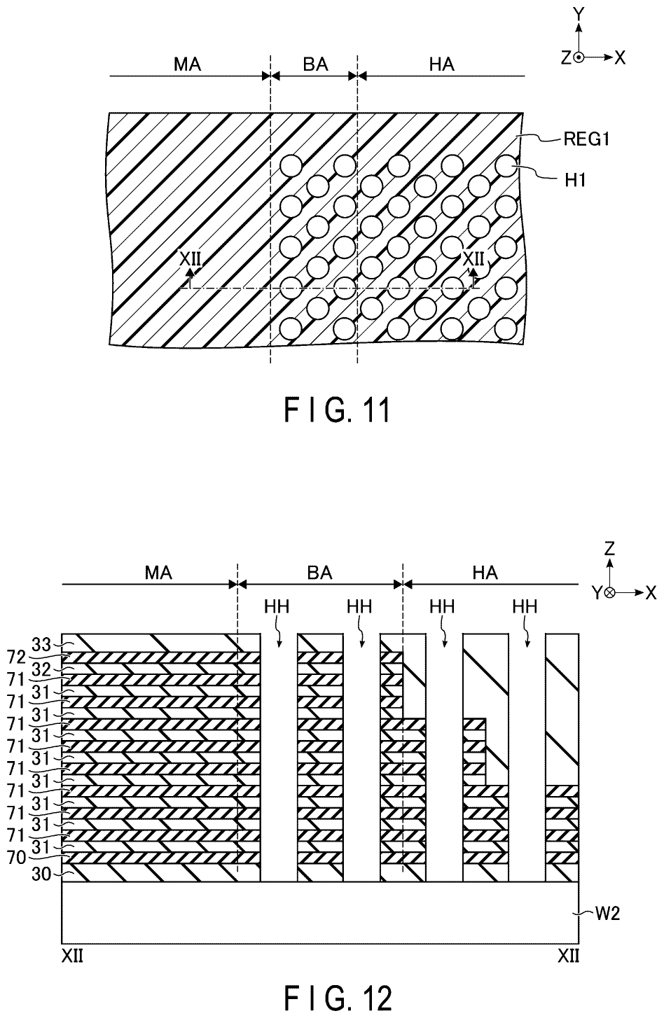

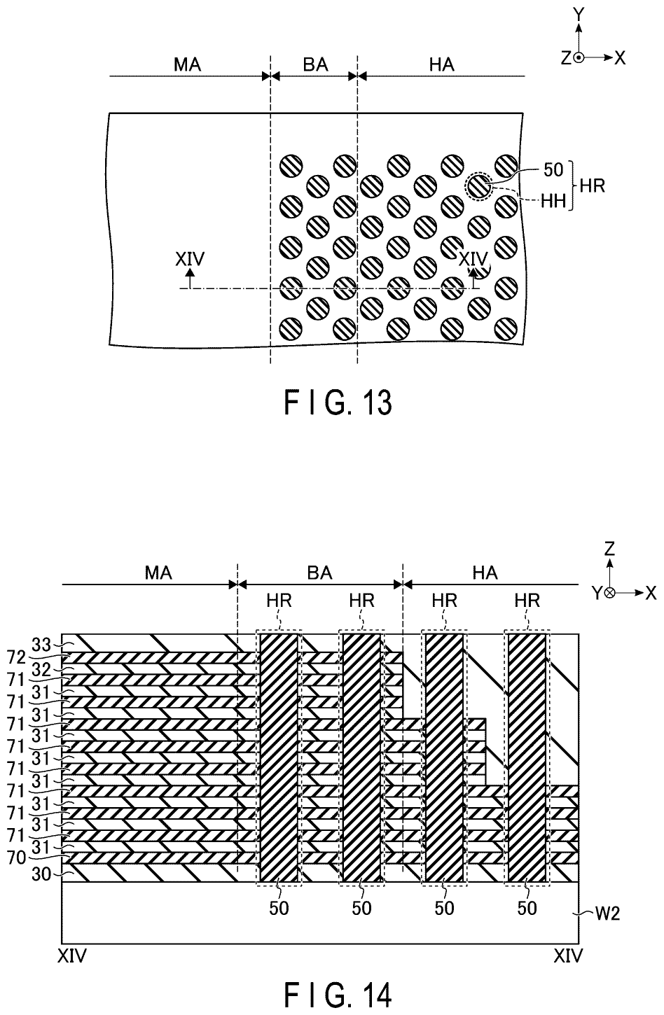

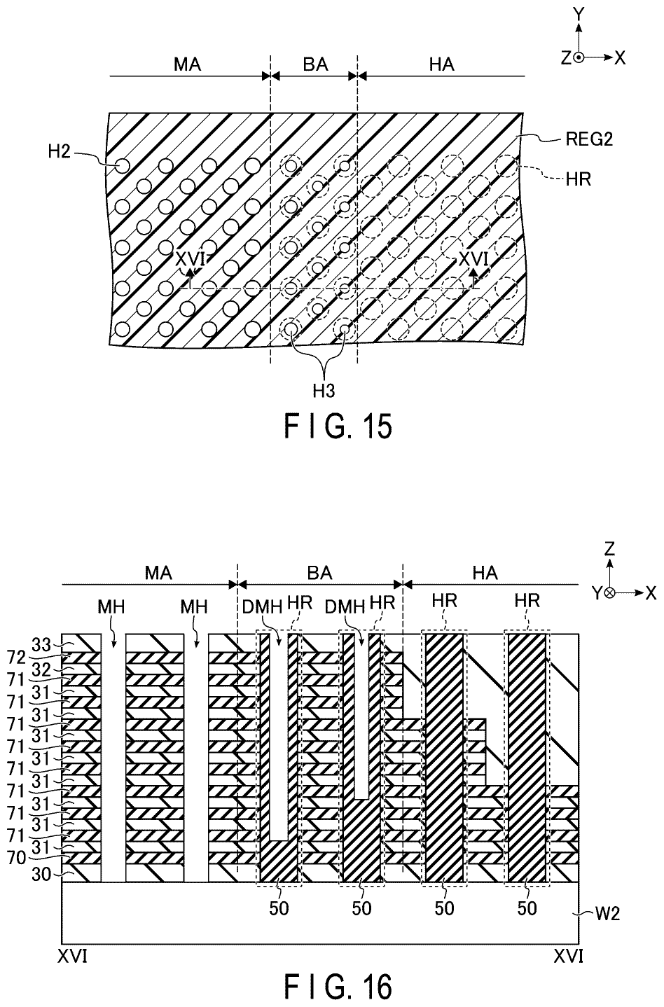

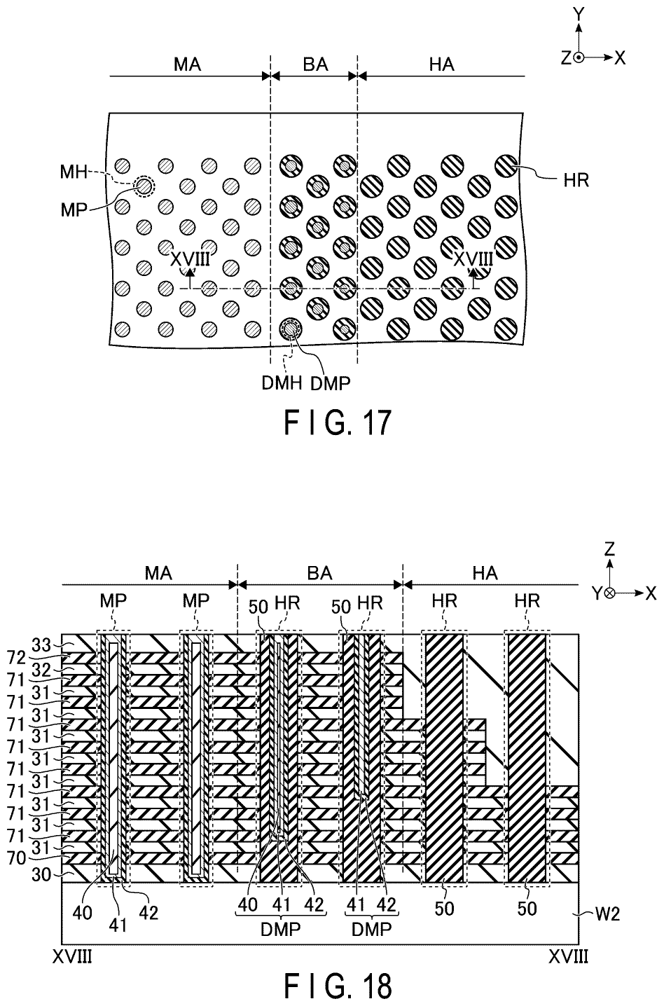

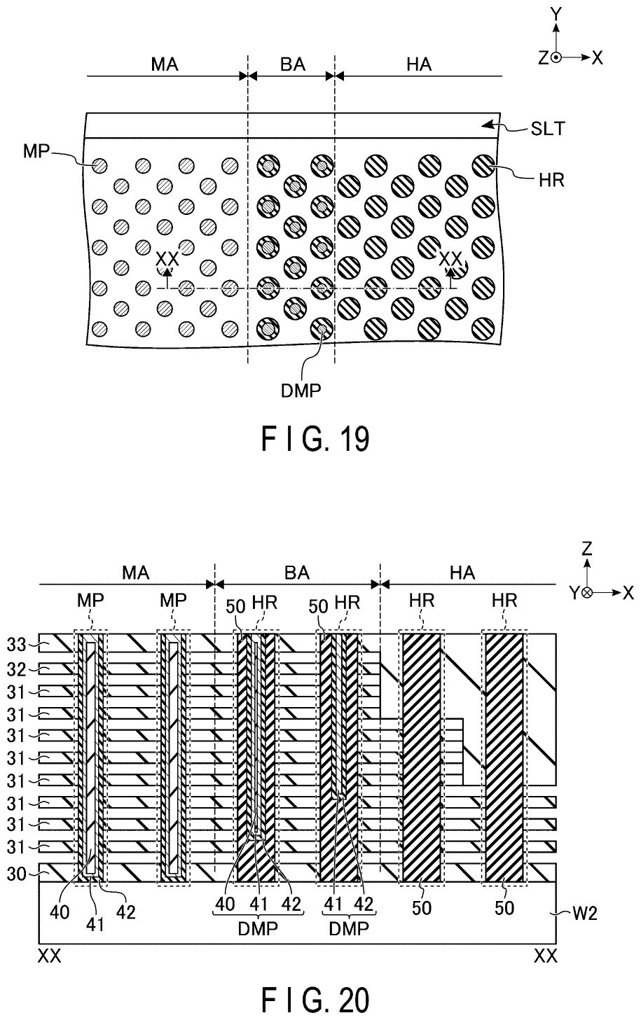

Next, a method for manufacturing the memory device 1 according to the first embodiment is described using FIGS. 11 to 20. Each of FIGS. 11, 13, 15, 17, and 19 is a plan view showing an example of a planar layout in the manufacturing process of the memory cell array 10 included in the memory device 1 according to the first embodiment. The planar layout referred to in the present item corresponds to a region in the vicinity of the boundary region BA of the memory cell array 10 shown in FIG. 8. Each of FIGS. 12, 14, 16, 18, and 20 is a cross-sectional view showing an example of a cross-sectional structure in the manufacturing process of the memory cell array 10 included in the memory device 1 according to the first embodiment. FIG. 12 corresponds to a cross section taken along line XII-XII of FIG. 11. FIG. 14 corresponds to a cross section taken along line XIV-XIV of FIG. 13. FIG. 16 corresponds to a cross section taken along line XVI-XVI of FIG. 15. FIG. 18 corresponds to a cross section taken along line XVIII-XVIII of FIG. 17. FIG. 20 corresponds to a cross section taken along line XX-XX of FIG. 19. In the present specification, the “stacked wiring portion” refers to a structure used to form stacked wiring lines including a plurality of word lines WL being arranged in the Z direction.

First, although illustration is omitted, sacrificial members 70 to 72 of the stacked wiring portion are formed. Specifically, first, a sacrificial member 70 is formed on an insulating layer 30. An insulating layer 31 and a sacrificial member 71 are alternately stacked on the sacrificial member 70. An insulating layer 32 and a sacrificial member 72 are sequentially formed on the uppermost sacrificial member 71. Then, a staircase structure of the sacrificial members 70 to 72 is formed in the hookup region HA by slimming processing or etching processing. Then, the level differences of the staircase structure are filled with an insulating layer 33, and the upper surface of the insulating layer 33 is planarized. The sacrificial members 70 to 72 are, for example, silicon nitride (SiN). The formation of the staircase structure of the sacrificial members 70 to 72 may be omitted depending on the design of the memory cell array 10.

Next, as shown in FIG. 11, a mask REG1 is formed. Specifically, first, a mask member (for example, carbon) used as a mask for etching processing of deep holes is formed on the insulating layer 33. Then, a resist material is applied onto the mask member. Then, the resist material is processed into a shape having a plurality of holes H1 by photolithography processing. The holes H1 are provided corresponding individually to positions where a plurality of support pillars HR are to be formed. After that, the mask member is processed by anisotropic etching processing using the resist material as a mask. As a result, the shape of the resist material is transferred to the mask member, and a mask REG1 having the holes H1 is formed.

Next, anisotropic etching processing using the mask REG1 as a mask is executed. Then, etching via the holes H1 proceeds, and a plurality of holes HH are formed as shown in FIG. 12. FIG. 12 shows a cross-sectional structure after the mask used at this time is removed. Each hole HH is provided to penetrate the insulating layers 30 and 33 and, out of the sacrificial members 70 to 72 and the insulating layers 31 and 32, a portion sandwiched between the insulating layers 30 and 33. A surface of the semiconductor substrate W2 is exposed in a bottom portion of each hole HH. That is, in the present processing, the semiconductor substrate W2 is used as an etching stopper. In the present processing, for example, RIE (reactive ion etching) is used.

Next, as shown in FIG. 13, each of the holes HH is filled with an insulating member 50. At this time, as shown in FIG. 14, a bottom portion of each insulating member 50 is in contact with the semiconductor substrate W2. Further, the side surface of each insulating member 50 is in contact with the insulating layer 33 and at least one of the insulating layers 30 to 32. After the insides of the holes HH are filled with the insulating member 50, an insulating film may be formed on the insulating member 50 and the stacked wiring portion, and thus the insulating layer 33 may be enlarged by accumulation.

Next, as shown in FIG. 15, a mask REG2 is formed. Specifically, first, a mask member (for example, carbon) used as a mask for etching processing of deep holes is formed on the insulating layer 33. Then, a resist material is applied onto the mask member. Then, the resist material is processed into a shape having a plurality of holes H2 and a plurality of holes H3 by photolithography processing. The holes H2 are provided corresponding individually to positions where a plurality of memory pillars MP are to be formed. The holes H3 are provided corresponding individually to positions where a plurality of dummy pillars DMP are to be formed. At this time, for the holes H3, a hole H3 nearer to an end row in the entire arrangement of holes H2 and holes H3 is likely to be formed with a smaller diameter. After that, the mask member is processed by anisotropic etching processing using the resist material as a mask. As a result, the shape of the resist material is transferred to the mask member, and a mask REG2 having the holes H2 and the holes H3 is formed.

Next, anisotropic etching processing using the mask REG2 as a mask is executed. Then, etching via the holes H2 and the holes H3 proceeds, and a plurality of memory holes MH and a plurality of holes DMH are formed as shown in FIG. 16. FIG. 16 shows a cross-sectional structure after the mask used at this time is removed. Each memory hole MH is provided to penetrate the insulating layers 30 to 33 and the sacrificial members 70 to 72. A surface of the semiconductor substrate W2 is exposed in a bottom portion of each memory hole MH. That is, in the present processing, the semiconductor substrate W2 is used as an etching stopper. Each hole DMH is provided by removing a part of the insulating member 50 forming the support pillar HR. A surface of the insulating member 50 is exposed on the side surface and the bottom surface of each hole DMH. The positions (heights) of the bottoms of the holes DMH vary based on the difference in diameter between corresponding holes H3. In the present processing, for example, RIE is used. In the RIE, in a case where the holes H3 are formed at the same pitch on the mask REG2, the progress of etching in the height direction (the Z direction) can be suppressed as the diameter of the hole H3 is smaller.

Next, as shown in FIG. 17, a memory pillar MP is formed in each memory hole MH, and a dummy pillar DMP is formed in each hole DMH. Specifically, a stacked film 42 (that is, a block insulating film 45, an insulating film 44, and a tunnel insulating film 43), a semiconductor layer 41, and a core member 40 are formed in this order on the side surface and the bottom surface of the memory hole MH. At this time, a stacked film 42, a semiconductor layer 41, and a core member 40 are formed in this order also on the side surface and the bottom surface of the hole DMH. According to the diameter of the hole DMH, some of the stacked film 42, the semiconductor layer 41, and the core member 40 may not be formed in the hole DMH. Then, a part of the core member 40 provided in an upper portion of the memory hole MH is removed, and a semiconductor layer 41 is formed in the portion where the core member 40 has been removed. As a result, as shown in FIG. 18, a structure corresponding to the memory pillar MP is formed in the memory hole MH. Similarly, a structure corresponding to the dummy pillar DMP is formed in the hole DMH. After that, the stacked film 42, the semiconductor layer 41, and the core member 40 above the insulating layer 33 are removed by CMP (chemical mechanical polishing) or the like.

Next, as shown in FIG. 19, slits SLT that divide the sacrificial members 70 to 72 on a block BLK basis are formed. Specifically, first, a not-illustrated insulating film is formed on the insulating layer 33 so as to protect the memory pillars MP, the dummy pillars DMP, and the support pillars HR. After that, slits SLT are formed by a combination of photolithography processing and anisotropic etching processing. Although illustration is omitted, the slits SLT divide the insulating layers 30 to 33 and the sacrificial members 70 to 72. By the present processing, a surface of the semiconductor substrate W2 is exposed in a bottom portion of the slit SLT.

Next, replacement processing is executed. Specifically, the sacrificial members 70 to 72 are selectively removed via the slits SLT as shown in FIG. 20 by wet etching processing with hot phosphoric acid or the like. At this time, the spaces where the sacrificial members 70 to 72 have been removed are maintained by the memory pillars MP and the support pillars HR. Then, a conductor is embedded via the slits SLT in the spaces where the sacrificial members 70 to 72 have been removed. CVD, for example, is used for the formation of a conductor in the present step. Then, the conductor formed in the slits SLT is removed by etchback processing or the like, and the conductor formed in the adjacent spaces is separated into a plurality of layers. Thereby, a conductive layer 21 functioning as a select gate line SGS, a plurality of conductive layers 22 each functioning as a word line WL, and a conductive layer 23 functioning as a select gate line SGD are formed. After that, an insulating member 37 is formed in the slits SLT, and the stacked wiring lines shown in FIGS. 6 and 9 are completed.

### <1-3>Effects of First Embodiment

In the case of the memory device 1 according to the first embodiment described hereinabove, the manufacturing cost of the memory device 1 can be suppressed. Details of effects of the first embodiment will now be described using a first comparative example and a second comparative example.

In a memory device having a structure in which memory cells are three-dimensionally stacked, a plurality of support pillars HR are provided in order to maintain the structure of a stacked wiring portion in a case where sacrificial members 70 to 72 are removed during replacement processing. In a manufacturing method in which memory pillars MP and support pillars HR are formed by different steps, holes DMH are arranged in a boundary region BA in order to assist the opening condition of memory holes MH of an end row during processing of a plurality of memory holes MH. However, it is difficult to control the depth of the hole DMH.

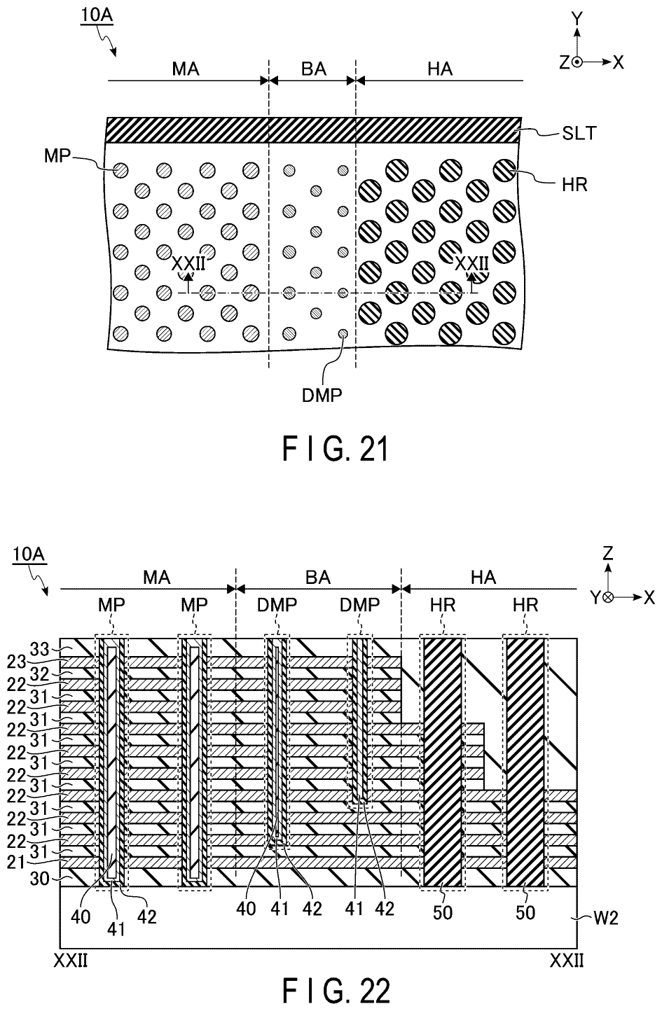

FIG. 21 is a plan view showing an example of a planar layout of a memory cell array 10A according to a first comparative example. FIG. 22 is a cross-sectional view taken along line XXII-XXII of FIG. 21, showing an example of a cross-sectional structure of the memory cell array 10A according to the first comparative example. As shown in FIG. 21, the first comparative example corresponds to a case where a plurality of support pillars HR are not formed in the boundary region BA. In the present example, as shown in FIG. 22, in the boundary region BA, the diameter of the dummy pillar DMP is small, and the bottom of the dummy pillar DMP does not reach the semiconductor substrate W2. In such a design, in the formation of stacked wiring lines, the layer structure of insulating layers 31 below dummy pillars DMP may collapse during replacement processing. Specifically, the insulating layer 31 may be bent in a portion that the dummy pillar DMP does not reach, and a filling defect of a conductor corresponding to the word line WL may occur.

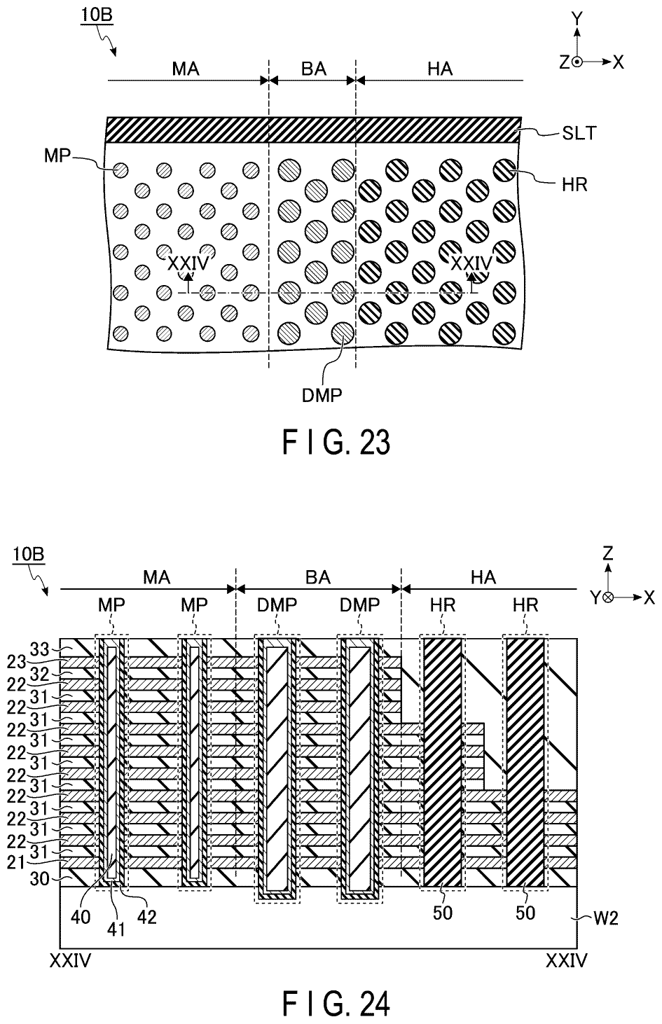

FIG. 23 is a plan view showing an example of a planar layout of a memory cell array 10B according to a second comparative example. FIG. 24 is a cross-sectional view taken along line XXIV-XXIV of FIG. 23, showing an example of a cross-sectional structure of the memory cell array 10B according to the second comparative example. As shown in FIG. 23, the second comparative example corresponds to a case where, in the boundary region BA, the diameter of the dummy pillar DMP is set larger than in the first comparative example. In this case, as shown in FIG. 24, the bottom of the dummy pillar DMP may reach the semiconductor substrate W2 in the boundary region BA. As a result, bending of the insulating layer 31 during replacement processing can be suppressed. On the other hand, in a case where the diameter of the dummy pillar DMP is set larger, over-etching on the semiconductor substrate W2 may occur during formation of the hole HH corresponding to the dummy pillar DMP. In this case, since the height of the bottom of the memory pillar MP and the height of the bottom of the dummy pillar DMP are different, level differences may occur at the time of removing the semiconductor substrate W2 after processing of bonding the semiconductor substrates W1 and W2. Then, a defect due to the generated level differences may occur.

In contrast, the memory device 1 according to the first embodiment has a structure in which the dummy pillar DMP and the support pillar HR overlap in the Z direction in the boundary region BA. For example, the support pillars HR formed in the boundary region BA can suppress bending of insulating layers 31 during replacement processing. Further, the support pillars HR formed in the boundary region BA can, during formation of the memory holes MH, tolerate the fact that dummy pillars DMP do not to reach the semiconductor substrate W2. That is, in the memory device 1 according to the first embodiment, the diameter of the dummy pillar DMP is designed to be small, and the occurrence of over-etching on the semiconductor substrate W2 and the occurrence of a defect caused by over-etching can be suppressed.

As hereinabove, the memory device 1 according to the first embodiment can suppress the occurrence of a defect in replacement processing and the occurrence of a defect caused by over-etching of the dummy pillar DMP. Therefore, the memory device 1 according to the first embodiment can improve the yield, and can suppress the manufacturing cost of the memory device 1.

### <2>Second Embodiment

In a second embodiment, a boundary region BA having a planar layout similar to that of the first embodiment is used for a memory cell array 10C including a plurality of tiers. In the following, differences of a memory device 1 according to the second embodiment from the first embodiment are mainly described.

### <2-1> Configuration

First, a configuration of the memory device 1 according to the second embodiment is described. The configuration of the memory device 1 according to the second embodiment is similar to that of the memory device 1 according to the first embodiment except that the structure of the memory cell array 10 is different. In the second embodiment, a case where each NAND string NS includes 16 memory cell transistors MT0 to MT15 connected to word lines WL0 to WL15, respectively, is described as an example. Hereinafter, the memory pillar MP of the memory device 1 according to the second embodiment is referred to as a “memory pillar MPa”.

### (1: Cross-sectional Structure of Memory Cell Array 10C)

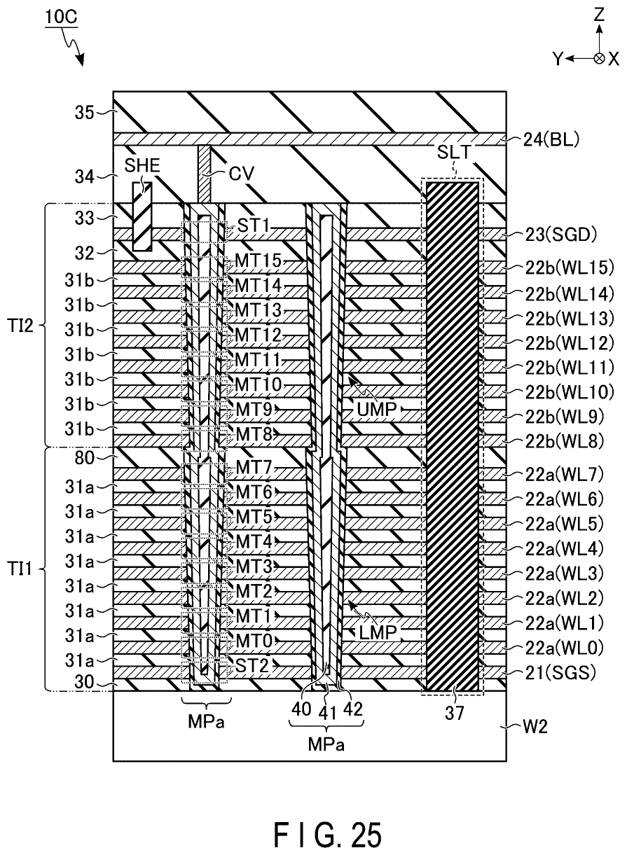

FIG. 25 is a cross-sectional view showing an example of a cross-sectional structure of the memory cell array 10C included in the memory device 1 according to the second embodiment. FIG. 25 shows an example of a structure of the memory cell array 10C formed on the semiconductor substrate W2 before being bonded to the semiconductor substrate W1, and shows coordinate axes with the semiconductor substrate W2 as a reference. As shown in FIG. 25, the memory cell array 10C includes, for example, a semiconductor substrate W2, conductive layers 21, 22a, 22b, 23, and 24, insulating layers 30, 31a, 31b, 32 to 35, and 80, memory pillars MPa, slits SLT and SHE, and contacts CV.

The memory cell array 10C is different from the memory cell array 10 of the first embodiment in the structure between the conductive layer 21 and the insulating layer 32. Specifically, an insulating layer 31a and a conductive layer 22a are alternately stacked on a conductive layer 21. An insulating layer 80 is provided on the uppermost conductive layer 22a. A conductive layer 22b and an insulating layer 31b are alternately stacked on the insulating layer 80. An insulating layer 32 is provided on the uppermost conductive layer 22b.

Each of the conductive layers 22a and 22b is, for example, formed in a plate shape spreading along the XY plane. The stacked eight conductive layers 22a are used as word lines WL0 to WL7, respectively, in this order from the conductive layer 21 side. The stacked eight conductive layers 22b are used as word lines WL8 to WL15, respectively, in this order from the conductive layer 21 side. Each of the conductive layers 22a and 22b contains, for example, tungsten. Hereinafter, a unit for dividing the process of forming holes for forming memory pillars MPa is referred to as a tier TI. In the present example, the memory cell array 10C includes tiers TI1 and TI2. The tier TIL includes eight conductive layers 22a. The tier TI2 includes eight conductive layers 22b.

The memory pillar MPa has a structure in which a plurality of pillars each provided to extend along the Z direction are coupled. In the present example, the memory pillar MPa includes two pillars coupled in the Z direction. Hereinafter, the two pillars are referred to as a lower pillar LMP and an upper pillar UMP. The lower pillar LMP is associated with the tier TI1. The lower pillar LMP is provided to penetrate each of the insulating layers 30, 31a, and 80 and the conductive layers 21 and 22a. The upper pillar UMP is provided on the lower pillar LMP, and is associated with the tier TI2. The upper pillar UMP is provided to penetrate each of the insulating layers 31b, 32, and 33 and the conductive layers 22b and 23. The coupled portion between the lower pillar LMP and the upper pillar UMP is included in a layer at the height at which the insulating layer 80 is provided.

The lower pillar LMP and the upper pillar UMP share the core member 40, the semiconductor layer 41, and the stacked film 42. That is, each of the core member 40, the semiconductor layer 41, and the stacked film 42 included in the memory pillar MPa is continuously provided between the lower pillar LMP and the upper pillar UMP. In the present example, each of the lower pillar LMP and the upper pillar UMP has an inverse tapered shape. In this case, the XY cross-sectional area of the upper end of the lower pillar LMP is larger than the XY cross-sectional area of the lower end of the upper pillar UMP. A crossing portion of the lower pillar LMP and the conductive layer 21 functions as a select transistor ST2. Crossing portions of the lower pillar LMP and the eight conductive layers 22a function individually as memory cell transistors MT0 to MT7 in this order from the bottom. Crossing portions of the upper pillar UMP and the eight conductive layers 22b function individually as memory cell transistors MT8 to MT15 in this order from the bottom. A crossing portion of the upper pillar UMP and the conductive layer 23 functions as a select transistor ST1.

The slit SLT of the second embodiment divides the conductive layers 21, 22a, 22b, and 23 and the insulating layers 30, 31a, 80, 31b, 32, and 33. That is, the slit SLT divides the wiring lines provided in the tiers TIL and TI2. In the slit SLT of the second embodiment, a conductor provided with a spacer of an insulator on its side wall may be provided to be insulated from these wiring lines. The slit SHE of the second embodiment divides at least the conductive layer 23 like in the first embodiment.

### (2: Cross-sectional Structure of Vicinity of Boundary Region BA of Memory Cell Array 10C)

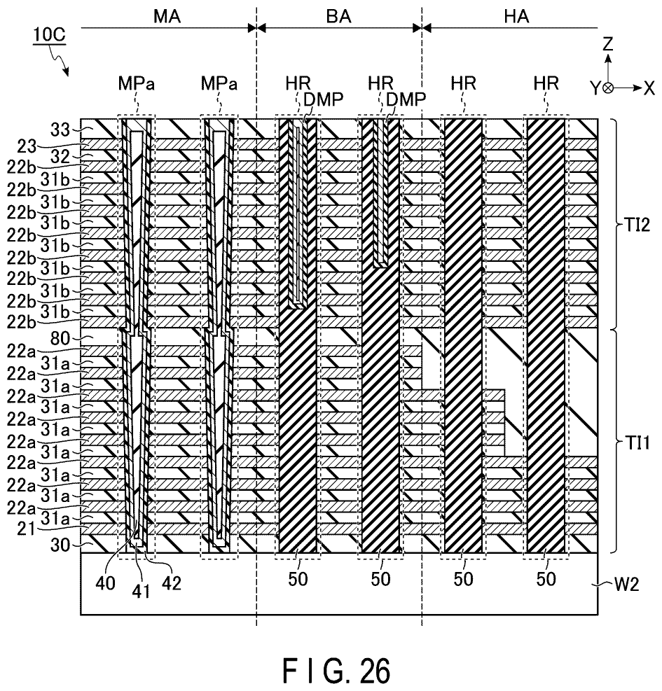

FIG. 26 is a cross-sectional view showing an example of a cross-sectional structure in the vicinity of the boundary region of the memory cell array 10C included in the memory device 1 according to the second embodiment. FIG. 26 shows an example of a structure of the memory cell array 10C formed on the semiconductor substrate W2 before being bonded to the semiconductor substrate W1, and shows coordinate axes with the semiconductor substrate W2 as a reference. As shown in FIG. 26, the support pillar HR of the second embodiment is provided to penetrate the tiers TIL and TI2. Specifically, the insulating member 50 forming the support pillar HR of the second embodiment penetrates, for example, each of the insulating layers 30, 31a, 80, 31b, 32, and 33 and the conductive layers 21, 22a, 22b, and 23. That is, the insulating member 50 is continuously provided between the tiers TI1 and TI2. Further, the side surface of the insulating member 50 forming the support pillar HR has a continuous shape over the tiers TIL and TI2. A bottom portion of each insulating member 50 of the second embodiment is in contact with the semiconductor substrate W2. The structure of each insulating member 50 of the second embodiment is similar between the hookup region HA and the boundary region BA.

The dummy pillar DMP of the second embodiment is, for example, included in the tier TI2 and not included in the tier TI1. Specifically, in the boundary region BA, the upper surface of each dummy pillar DMP is aligned with the upper surface of the memory pillar MPa. The upper surface of the dummy pillar DMP may or may not be aligned with the upper surface of the support pillar HR. Then, the side surface and a bottom portion of each dummy pillar DMP are covered with the insulating member 50 (the support pillar HR) overlapping in the Z direction. The length in the Z direction of each dummy pillar DMP is shorter than the height of the tier TI2. The configuration is not limited thereto, and the boundary region BA may include a dummy pillar DMP extending from an upper portion of the tier TI2 up to partway through the tier TI1.

In the hookup region HA of the second embodiment, each of the stacked wiring lines of the tier TIL and the stacked wiring lines of the tier TI2 included in the memory cell array 10C can have a terrace portion. In the present example, a case where the tier TIL includes terrace portions of two conductive layers 22 is illustrated. In the present example, the level differences formed by the terrace portions in the tier TIL are filled with the insulating layer 80. The level differences formed by the terrace portions in the tier TI2 are filled with the insulating layer 33 (not illustrated).

### <2-2>Manufacturing Method

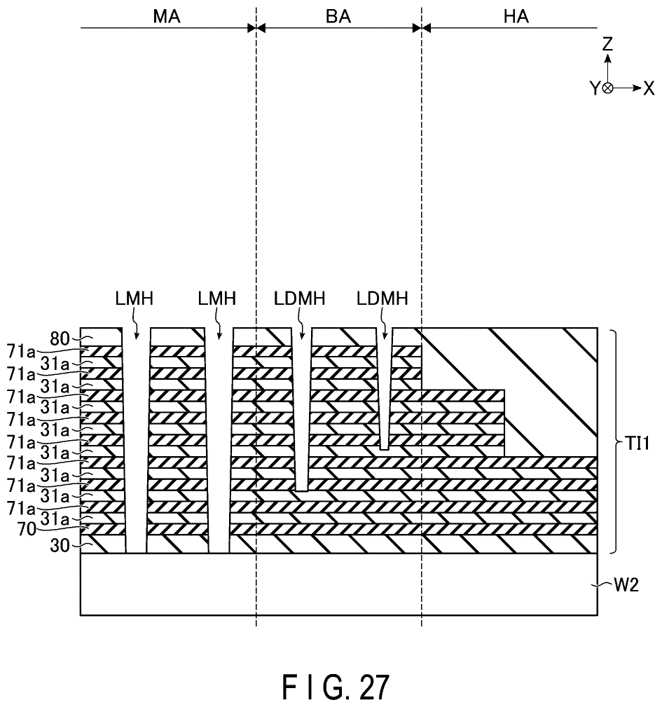

Next, a method for manufacturing the memory device 1 according to the second embodiment is described using FIGS. 27 to 33. Each of FIGS. 27, 28, 29, 30, 31, 32, and 33 is a cross-sectional view showing an example of a cross-sectional structure in the manufacturing process of the memory cell array 10C included in the memory device 1 according to the second embodiment. The cross-sectional structure referred to in the present item corresponds to a region in the vicinity of the boundary region BA of the memory cell array 10C shown in FIG. 26.

First, although illustration is omitted, sacrificial members 70 and 71a of a stacked wiring portion corresponding to the tier TIL are formed. Specifically, first, a sacrificial member 70 is formed on an insulating layer 30. An insulating layer 31a and a sacrificial member 71a are alternately stacked on the sacrificial member 70. Then, a staircase structure of the sacrificial members 70 and 71a is formed in the hookup region HA by slimming processing or etching processing. Then, the level differences of the staircase structure are filled with an insulating layer 80, and the upper surface of the insulating layer 80 is planarized. The sacrificial members 70 and 71a are, for example, silicon nitride (SiN). The formation of the staircase structure of the sacrificial members 70 and 71a may be omitted depending on the design of the memory cell array 10C.

Next, a mask REG2 (not illustrated) similar to that of the first embodiment is formed, and anisotropic etching processing using the mask REG2 as a mask is executed. Then, etching via a plurality of holes H2 and a plurality of holes H3 proceeds, and a plurality of memory holes LMH and a plurality of holes LDMH are formed as shown in FIG. 27. Each memory hole LMH is provided to penetrate the insulating layers 30, 31a, and 80 and the sacrificial members 70 and 71a. A surface of the semiconductor substrate W2 is exposed in a bottom portion of each memory hole LMH. That is, in the present processing, the semiconductor substrate W2 is used as an etching stopper. Each hole LDMH is provided to penetrate a part of the stacked structure of the insulating layers 30, 31a, and 80 and the sacrificial members 70 and 71a. The bottom of each hole LDMH is stopped partway through the stacked structure (the tier TI1) of the insulating layers 30, 31a, and 80 and the sacrificial members 70 and 71a. In the present processing, for example, RIE is used.

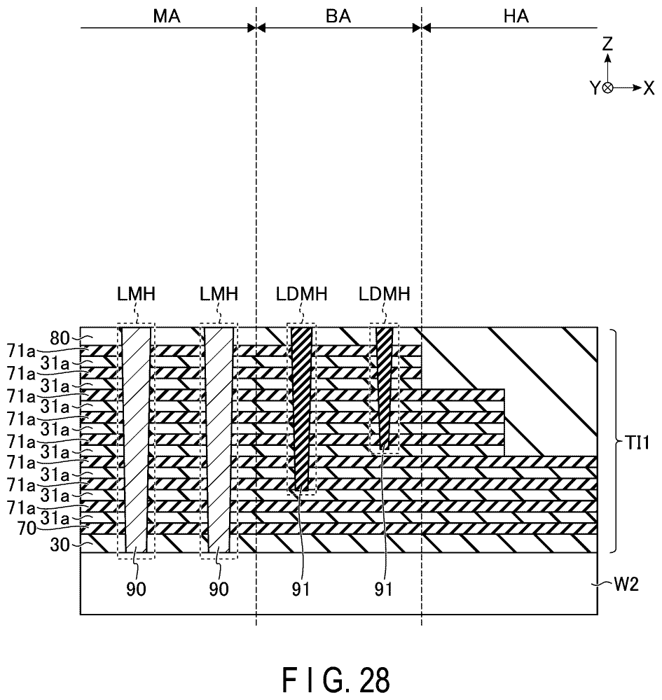

Next, as shown in FIG. 28, a sacrificial member 90 is formed in each memory hole LMH, and an insulating member 91 is formed in each hole LDMH. The material used as the sacrificial member 90 and the material used as the insulating member 91 are different. Thus, the formation of the sacrificial member 90 and the formation of the insulating member 91 are performed in separate steps. The sacrificial member 90 is, for example, carbon (C). The insulating member 91 is, for example, silicon oxide (SiO₂).

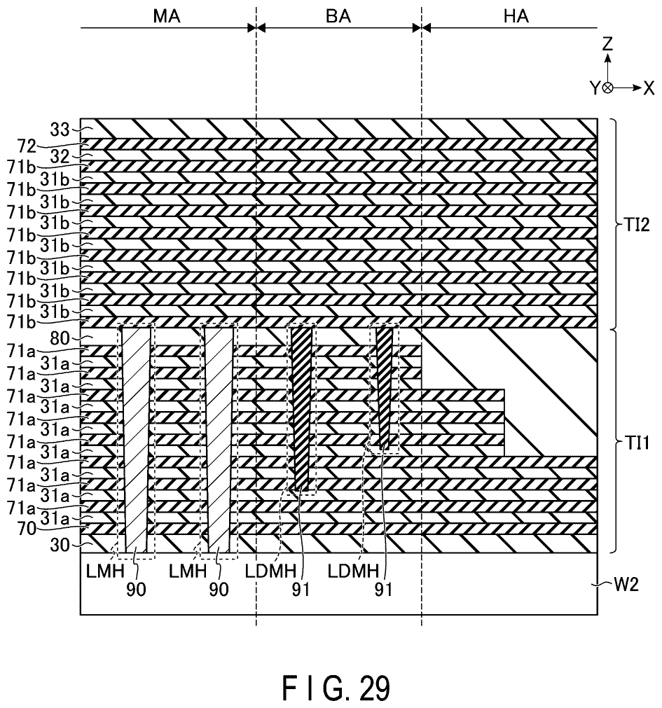

Next, as shown in FIG. 29, sacrificial members 71b and 72 of a stacked wiring portion corresponding to the tier TI2 are formed. Specifically, first, a sacrificial member 71b and an insulating layer 31b are alternately stacked on the insulating layer 80. An insulating layer 32 and a sacrificial member 72 are sequentially formed on the uppermost sacrificial member 71b. Then, a staircase structure (not illustrated) of the sacrificial members 71b and 72 is formed in the hookup region HA by slimming processing or etching processing. Then, the level differences of the staircase structure are filled with an insulating layer 33, and the upper surface of the insulating layer 33 is planarized. The sacrificial members 71b and 72 are, for example, silicon nitride (SiN). The formation of the staircase structure of the sacrificial members 71b and 72 may be omitted depending on the design of the memory cell array 10C.

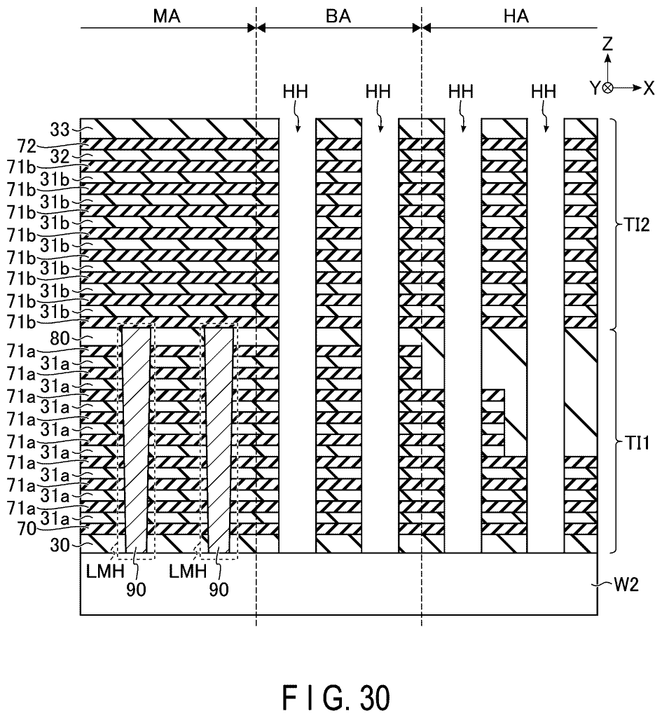

Next, a mask REG1 (not illustrated) similar to that of the first embodiment is formed, and anisotropic etching processing using the mask REG1 as a mask is executed. Then, etching via a plurality of holes H1 proceeds, and a plurality of holes HH are formed as shown in FIG. 30. Each hole HH of the second embodiment is provided to penetrate the insulating layers 30, 33, and 80 and, out of the sacrificial members 70, 71a, 71b, and 72 and the insulating layers 31, 31a, 31b, and 32, a portion sandwiched between the insulating layers 30 and 33. A surface of the semiconductor substrate W2 is exposed in a bottom portion of each hole HH. That is, in the present processing, the semiconductor substrate W2 is used as an etching stopper. Thus, each hole HH of the second embodiment is provided to penetrate the stacked wiring portions of the tiers TIL and TI2. By the present processing, each hole HH removes a part or whole of the insulating member 91 provided in the tier TI1.

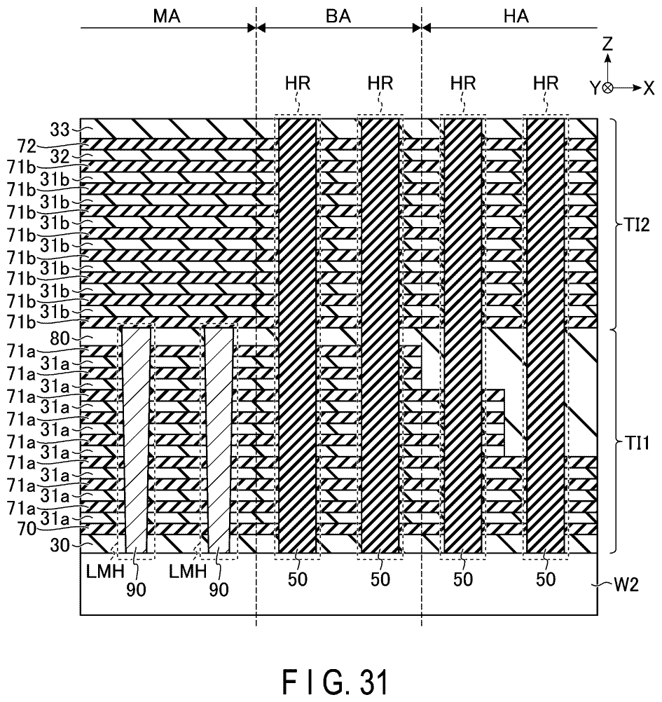

Next, as shown in FIG. 31, insulating members 50 are formed, and each of the holes HH is filled with the insulating member 50. At this time, a bottom portion of each insulating member 50 is in contact with the semiconductor substrate W2. Further, the side surface of each insulating member 50 is in contact with the insulating layers 33 and 80 and at least one of the insulating layers 30, 31a, 31b, and 32.

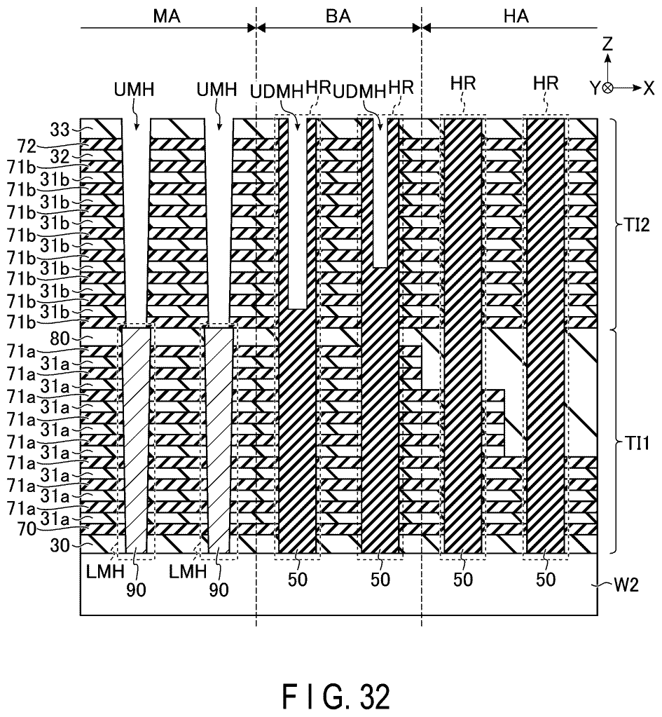

Next, a mask REG2 (not illustrated) similar to that of the first embodiment is formed, and anisotropic etching processing using the mask REG2 as a mask is executed. Then, etching via a plurality of holes H2 and a plurality of holes H3 proceeds, and a plurality of memory holes UMH and a plurality of holes UDMH are formed as shown in FIG. 32. Each memory hole UMH is provided to penetrate the insulating layers 31b and 33 and the sacrificial members 71b and 72. In a bottom portion of each memory hole UMH, the upper surface of the sacrificial member 90 of the associated memory hole LMH is exposed. That is, in the present processing, the sacrificial member 90 of the memory hole LMH is used as an etching stopper during formation of the memory hole UMH. Each hole UDMH is provided by removing a part of the insulating member 50 forming the support pillar HR. A surface of the insulating member 50 is exposed on the side surface and the bottom surface of each hole UDMH. The positions (heights) of the bottoms of the holes UDMH vary based on the difference in diameter between corresponding holes H3. In the present processing, for example, RIE is used.

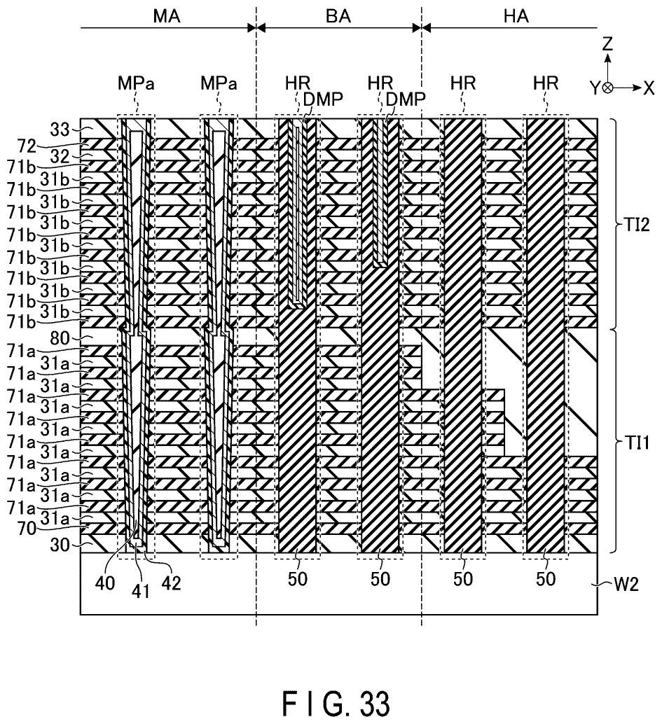

Next, the sacrificial member 90 in each memory hole LMH is removed via the corresponding memory hole UMH by, for example, wet etching. Then, as shown in FIG. 33, a memory pillar MPa is formed in a pair of coupled memory holes LMH and UMH, and a dummy pillar DMP is formed in each hole UDMH. Specifically, a stacked film 42 (that is, a block insulating film 45, an insulating film 44, and a tunnel insulating film 43), a semiconductor layer 41, and a core member 40 are formed in this order on the side surface and the bottom surface of the coupled memory holes LMH and UMH. At this time, a stacked film 42, a semiconductor layer 41, and a core member 40 are formed in this order also on the side surface and the bottom surface of the hole UDMH. According to the diameter of the hole UDMH, some of the stacked film 42, the semiconductor layer 41, and the core member 40 may not be formed in the hole UDMH. Then, a part of the core member 40 provided in an upper portion of the coupled memory holes LMH and UMH is removed, and a semiconductor layer 41 is formed in the portion where the core member 40 has been removed. As a result, as shown in FIG. 33, a structure corresponding to the memory pillar MPa is formed in the coupled memory holes LMH and UMH. Similarly, a structure corresponding to the dummy pillar DMP is formed in the hole UDMH. After that, the stacked film 42, the semiconductor layer 41, and the core member 40 above the insulating layer 33 are removed by CMP or the like.

Next, although illustration is omitted, slits SLT that divide the sacrificial members 70, 71a, 71b, and 72 on a block BLK basis are formed, and replacement processing is executed. Specifically, the sacrificial members 70, 71a, 71b, and 72 are selectively removed via the slits SLT by wet etching processing with hot phosphoric acid or the like. At this time, the spaces where the sacrificial members 70, 71a, 71b, and 72 have been removed are maintained by the memory pillars MPa and the support pillars HR. Then, a conductor is embedded via the slits SLT in the spaces where the sacrificial members 70, 71a, 71b, and 72 have been removed. CVD, for example, is used for the formation of a conductor in the present step. After that, the conductor formed in the slits SLT is removed by etchback processing or the like, and the conductor formed in the adjacent spaces is separated into a plurality of layers. Thereby, a conductive layer 21 functioning as a select gate line SGS, a plurality of conductive layers 22a and 22b each functioning as a word line WL, and a conductive layer 23 functioning as a select gate line SGD are formed. After that, an insulating member 37 is formed in the slits SLT, and the stacked wiring lines shown in FIGS. 25 and 26 are completed.

### <2-3>Effects of Second Embodiment

As described hereinabove, the memory device 1 according to the second embodiment includes memory pillars MPa formed in a plurality of tiers, and has a structure in which a plurality of dummy pillars DMP and a plurality of support pillars HR overlap in the Z direction in the boundary region BA. Also in such a case, like in the first embodiment, the memory device 1 according to the second embodiment can suppress the occurrence of a defect in replacement processing and the occurrence of a defect caused by over-etching of the dummy pillar DMP. Therefore, the memory device 1 according to the second embodiment can improve the yield, and can suppress the manufacturing cost of the memory device 1.

### <3>Modifications, etc.

The memory device 1 described hereinabove can be variously modified.

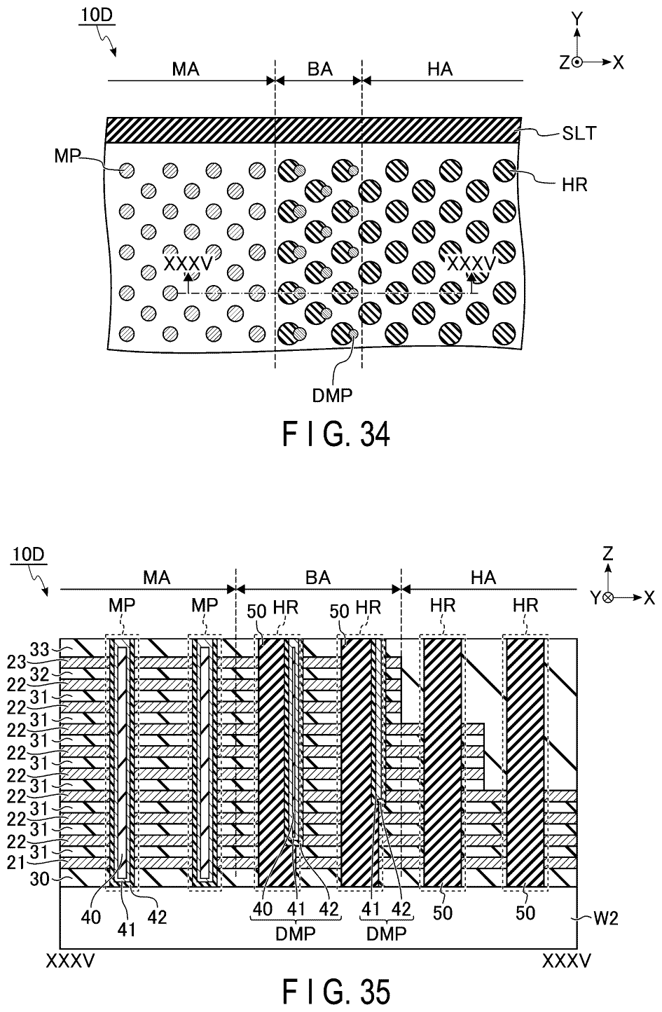

FIG. 34 is a plan view showing an example of a planar layout of a memory cell array 10D according to a first modification. FIG. 35 is a cross-sectional view taken along line XXXV-XXXV of FIG. 34, showing an example of a cross-sectional structure of the memory cell array 10D according to the first modification. As shown in FIG. 34, the first modification corresponds to a case where the positions of a plurality of dummy pillars DMP and a plurality of support pillars HR are misaligned in the boundary region BA. That is, the first modification corresponds to a state where the dummy pillar DMP and the support pillar HR partially overlap. In this case, as shown in FIG. 35, a part of the stacked film 42 of the dummy pillar DMP is in contact with at least one of the conductive layers 21 to 23. Thus, even in a case where the positions of the dummy pillar DMP and the support pillar HR are misaligned in the boundary region BA, similar effects to those of the first embodiment can be obtained.

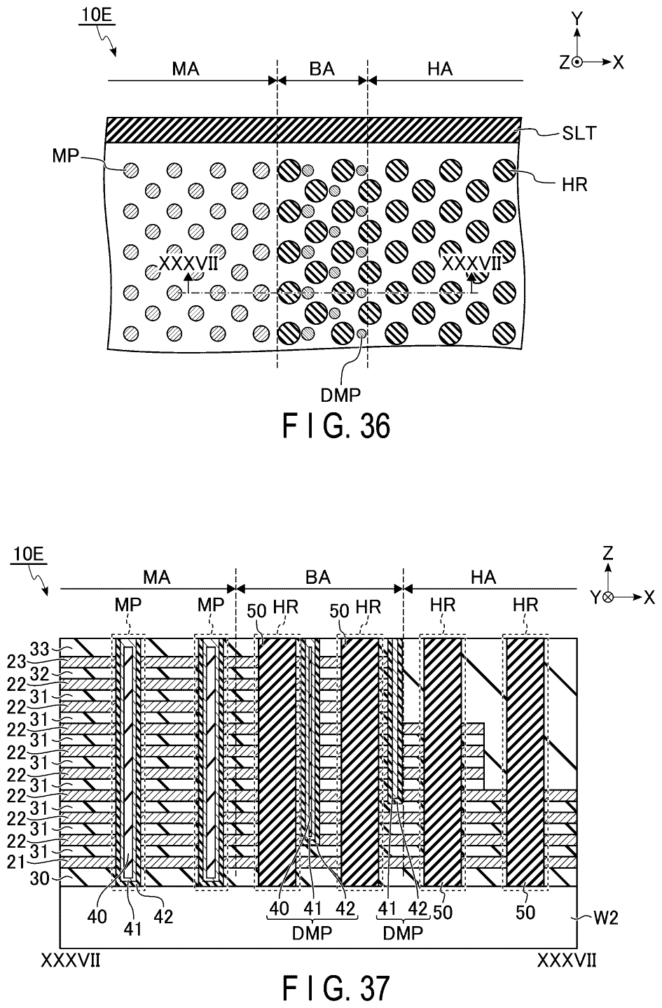

FIG. 36 is a plan view showing an example of a planar layout of a memory cell array 10E according to a second modification. FIG. 37 is a cross-sectional view taken along line XXXVII-XXXVII of FIG. 36, showing an example of a cross-sectional structure of the memory cell array 10E according to the second modification. As shown in FIG. 36, the second modification corresponds to a case where a plurality of dummy pillars DMP and a plurality of support pillars HR are apart (do not overlap) in the boundary region BA. In this case, as shown in FIG. 37, the side surface of the dummy pillar DMP is in contact with at least one of the conductive layers 21 to 23. Thus, even in a case where the dummy pillar DMP and the support pillar HR are apart in the boundary region BA, similar effects to those of the first embodiment can be obtained.

The structures described in the first modification and the second modification can be caused by superposition misalignment in photolithography processing. The larger the overlap between the support pillar HR and the dummy pillar DMP in the boundary region BA is, the more the increase in wiring resistance due to the formation of the dummy pillar DMP can be suppressed. Thus, although the numbers of rows, the numbers of columns, and the pitches of support pillars HR and dummy pillars DMP arranged in a staggered configuration in the boundary region BA and between two adjacent slits SLT may be different from each other, they are preferably the same. In the second embodiment, in a case where superposition misalignment occurs between the time of forming memory holes LMH and holes LDMH of the tier TIL and the time of forming holes HH of the tiers TIL and TI2, the insulating member 91 formed in the hole LDMH can remain in the memory device 1.

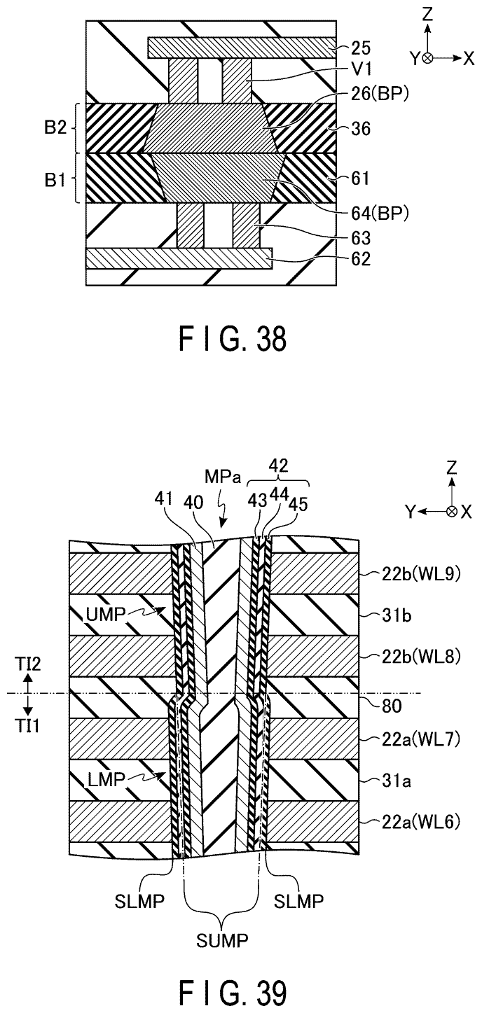

FIG. 38 is a cross-sectional view showing an example of a detailed cross-sectional structure of the vicinity of two bonding pads BP arranged to face each other. FIG. 38 shows a conductive layer 64 (a bonding pad BP) formed using a semiconductor substrate W1 (not illustrated), a conductive layer 26 (a bonding pad BP) formed using a semiconductor substrate W2 (not illustrated), and some contacts 63 and V1 and conductive layers 62 and 25 connected to these bonding pads BP. As shown in FIG. 38, the two bonding pads BP arranged to face each other can have different tapered shapes based on the etching direction during formation. Specifically, the conductive layer 64 formed using the semiconductor substrate W1 has, for example, an inverse tapered shape. The conductive layer 26 formed using the semiconductor substrate W2 has, for example, a tapered shape. Therefore, regarding the shape of a cross section along the Z direction in a portion where the conductive layer 64 and the conductive layer 26 are joined, the side wall of the portion may not have a straight-lined shape but the portion may forms a non-rectangular shape in the cross section. Also, the shapes of two bonding pads BP arranged to face each other in other portions can be formed in a similar manner to the conductive layers 26 and 64. Further, a set of two bonding pads BP arranged to face each other can be joined in a shifted manner according to alignment at the time of bonding processing. Therefore, a step can be formed at levels of the upper surface of the conductive layer 64 and the lower surface of the conductive layer 26. A set of two bonding pads BP arranged to face each other may have a boundary, or may be integrated. A bonding pad BP and contacts 63 and V1 connected to the bonding pad BP may be integrally formed. Pluralities of contacts 63 and V1 may be connected to a corresponding bonding pad BP. For example, the conductive layer 64 may be connected to the conductive layer 62 via a plurality of contacts 63. Similarly, the conductive layer 26 may be connected to the conductive layer 25 via a plurality of contacts V1.

FIG. 39 is a cross-sectional view showing an example of a detailed cross-sectional structure of a boundary portion between the first tier TIL and the second tier TI2 included in the memory pillar MPa included in the memory device 1 according to the second embodiment. As shown in FIG. 39, for example, in a YZ cross section, the upper end of the lower memory pillar LMP may have a rounded shape instead of an angular shape. In this case, it cannot be said that the XY cross-sectional area of the upper end of the lower memory pillar LMP is clearly larger than the XY cross-sectional area of the lower end of the upper memory pillar UMP. However, the shape of the side surface of the memory pillar MPa is discontinuous in a boundary portion between the lower memory pillar LMP and the upper memory pillar UMP. Specifically, for example, in a YZ cross section, the side surface SLMP of the lower memory pillar LMP deviates from an extension line of the side surface SUMP of the upper memory pillar UMP indicated by the alternate long and short dash line in FIG. 39. Misalignment of the two side surfaces SLMP and SUMP may occur for any cross section including the Z direction, such as an XZ cross section. In the present specification, the boundary portion of the memory pillar MP in two tiers TI adjacent in the Z direction can be specified based on a discontinuous portion in the shape of the side surface of the memory pillar MP. The memory pillar MPa may have a structure in which three or more pillars each provided to extend along the Z direction are coupled. Also in such a case, the memory pillar MPa can have a structure like that shown in FIG. 39 in a boundary portion between adjacent tiers TI.

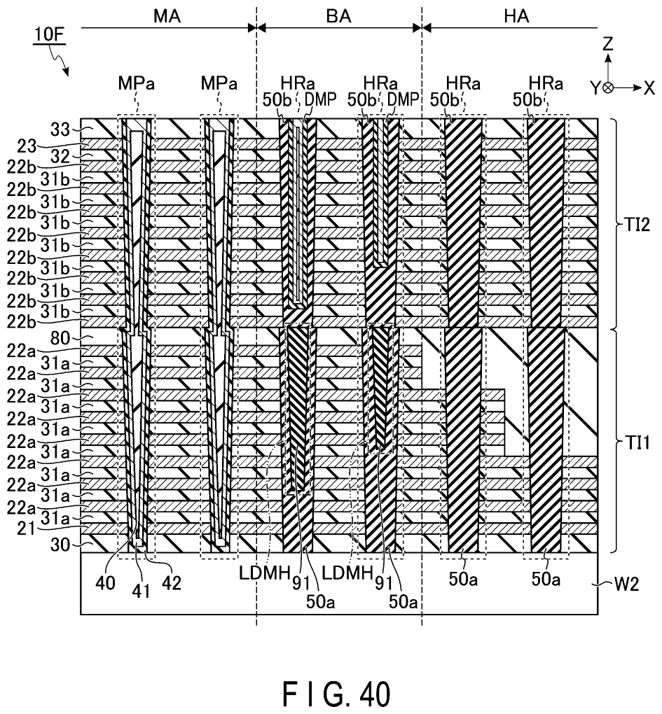

FIG. 40 is a cross-sectional view showing an example of a cross-sectional structure of a memory cell array 10F according to a third modification. As shown in FIG. 40, the third modification corresponds to a case where the structure of the support pillar HR and the dummy pillar DMP described in the first embodiment is also formed for each tier TI. Specifically, the memory cell array 10F according to the third modification has a structure in which the support pillar HR in the second embodiment is replaced with a support pillar HRa and the insulating member 91 corresponding to the hole LDMH remains. The support pillar HRa includes an insulating member 50a provided corresponding to the tier TI1 and an insulating member 50b provided corresponding to the tier TI2. The shape of the side surface of the insulating member 50a and the shape of the side surface of the insulating member 50b are discontinuous. The dummy pillar DMP overlaps with the support pillar HRa in the Z direction, and is provided by removing a part of the insulating member 50b. The insulating member 91 corresponding to the hole LDMH overlaps with the support pillar HRa in the Z direction, and is provided by removing a part of the insulating member 50a. Thus, also in a case where the support pillar HR is provided for each tier TI, similar effects to those of the second embodiment can be obtained. In the memory cell array 10F according to the third modification, a sacrificial member 90 may be formed in the hole LDMH instead of the insulating member 91.

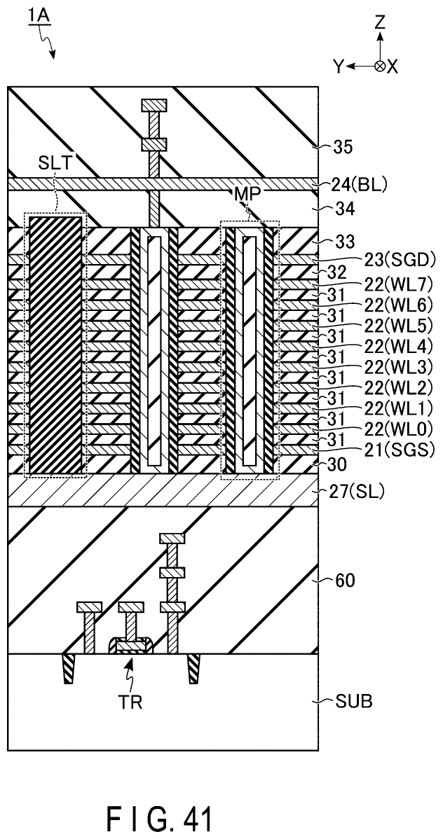

FIG. 41 is a cross-sectional view showing an example of a cross-sectional structure of a memory device 1A according to a fourth modification. As shown in FIG. 41, the fourth modification corresponds to a case where a memory device 1A is formed using one semiconductor substrate SUB and a CMOS circuit is provided below the memory cell array 10. Thus, also in a case where the memory device 1A is not formed using a plurality of semiconductor substrates, penetration of the dummy pillar DMP to the insulating layer 60 can be suppressed by the support pillar HR and the dummy pillar DMP being formed in the boundary region BA in a similar manner to the first embodiment. Thereby, the occurrence of a defect caused by interference of a bottom portion of the dummy pillar DMP with the CMOS circuit formed below the memory cell array 10 is suppressed. As a result, the memory device 1A according to the fourth modification can improve the yield, and can suppress the manufacturing cost of the memory device 1A.

In the above embodiments, each of the circuit configuration, the planar layout, and the cross-sectional structure of the memory device 1 can be changed as appropriate. The memory pillar MP may have a structure in which a pillar corresponding to a select gate line SGD and a pillar corresponding to a word line WL are coupled. The memory pillar MP and a bit line BL may be connected by a plurality of contacts coupled in the Z direction. A conductive layer may be inserted into the coupled portion between contacts. The numbers of wiring layers and contacts included in the memory device 1 can be changed according to the circuit design, as appropriate. The memory pillar MP may have a tapered shape, an inverse tapered shape, or a bowing shape. The slit SLT may have a tapered shape, an inverse tapered shape, or a bowing shape. The XY cross-sectional structure of each of the memory pillar MP and the support pillar HR may be a circular shape or an elliptical shape. In the present specification, the “XY cross-sectional area” corresponds to a cross-sectional area in a cross section parallel to the semiconductor substrate W1 or W2. Each wiring line in the stacked wiring lines may include a metal oxide film around a conductor such as tungsten. The conductive layer alternately stacked with the insulating layer in the stacked wiring lines may be regarded as a configuration including such a metal oxide film.

The manufacturing processes described in the above embodiments are merely examples. For example, other processing may be inserted between manufacturing steps, and the order of the manufacturing steps may be changed to the extent that no problem occurs. In the present specification, “connection” refers to being electrically connected, and does not exclude, for example, being connected via another element. “Electrically connected” may be connection via an insulator as long as operations similar to those in a case of being electrically connected can be performed. The “tapered shape” refers to a shape that becomes thinner with distance from a member taken as a reference. The “inverse tapered shape” refers to a shape that becomes thicker with distance from a member taken as a reference. “Columnar” refers to a structure provided in a hole formed in the manufacturing process of the memory device 1. The “diameter” refers to the inner diameter of a hole or the outer diameter of a pillar in a cross section (an XY cross section) parallel to a surface of a substrate. The “semiconductor substrate” may be referred to simply as a “substrate”. The “semiconductor layer” may be referred to as a “conductive layer”. The “region” may be regarded as a configuration included by a substrate. For example, in a case where it is provided that a semiconductor substrate W1 includes a memory region MA and a hookup region HA, the memory region MA and the hookup region HA are associated with different regions above the semiconductor substrate W1. The “height” corresponds to, for example, the spacing in the Z direction between a configuration of a measurement object and the semiconductor substrate W1. As a reference of “height”, a configuration other than the semiconductor substrate W1 may be used. The “top (planar) view” corresponds to, for example, viewing the front surface of the semiconductor substrate W1 from the vertical direction of the semiconductor substrate W1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a substrate including a first region, a second region, and a third region arranged in order in a first direction;
a plurality of first conductive layers arranged in a second direction crossing the first direction above the substrate;
a plurality of memory pillars provided in the first region, each of the memory pillars having a portion crossing the first conductive layers and including a stacked film;
a plurality of first pillars provided in the second region and the third region, each of the first pillars having a portion crossing at least one of the first conductive layers and having a configuration different from a configuration of each of the memory pillars; and
a plurality of second pillars provided in the second region, each of the second pillars having a portion crossing at least one first conductive layer among the first conductive layers and including the stacked film.

2. The memory device of claim 1, wherein
in the second region, at least a part of each of the second pillars overlaps with any one of the first pillars in the second direction.

3. The memory device of claim 1, wherein
each of the second pillars is apart from the first conductive layers.

4. The memory device of claim 1, wherein
the first pillars are arranged in a lattice configuration in the second region,
the second pillars are arranged in a lattice configuration in the second region, and
numbers of rows and columns of the second pillars arranged in the second region are same as numbers of rows and columns of the first pillars arranged in the second region, respectively.

5. The memory device of claim 1, wherein
the first pillars are arranged in a lattice configuration in the second region,
the second pillars are arranged in a lattice configuration in the second region, and
a pitch of the second pillars arranged in the second region is same as a pitch of the first pillars arranged in the second region.

6. The memory device of claim 1, wherein
at least one second pillar among the second pillars is shorter than each of the memory pillars in the second direction.

7. The memory device of claim 1, wherein
a diameter of each of the second pillars is smaller than a diameter of each of the first pillars in the second region.

8. The memory device of claim 7, wherein
a diameter of at least one second pillar among the second pillars is smaller than a diameter of each of the memory pillars.

9. The memory device of claim 1, wherein
a length in the second direction of each of the memory pillars is substantially equal to a length in the second direction of each of the first pillars.

10. The memory device of claim 1, wherein
each of the memory pillars includes a first portion included in a first tier and a second portion included in a second tier arranged in the second direction with the first tier above the substrate, and a shape of a side surface of the first portion and a shape of a side surface of the second portion are discontinuous.

11. The memory device of claim 10, wherein
each of the first pillars includes a first insulating member continuously provided between the first tier and the second tier.

12. The memory device of claim 10, further comprising
a plurality of third pillars arranged in the second region, each of the third pillars having a portion crossing at least one other first conductive layer among the first conductive layers and including a second insulating member, wherein
the second pillars are included in the second tier, and
the third pillars are included in the first tier.

13. The memory device of claim 12, wherein
each of the first pillars includes a third portion included in the first tier and a fourth portion included in the second tier, and a shape of a side surface of the third portion and a shape of a side surface of the fourth portion are discontinuous.

14. The memory device of claim 1, wherein
each of the memory pillars further includes a semiconductor layer, and
the stacked film includes a tunnel insulating film surrounding a side surface of the semiconductor layer, a charge storage layer surrounding a side surface of the tunnel insulating film, and a block insulating film surrounding a side surface of the charge storage layer.

15. The memory device of claim 14, wherein
a film thickness of the stacked film included in each of the second pillars and a film thickness of the stacked film included in each of the memory pillars are substantially same.

16. The memory device of claim 1, wherein
each of the first pillars includes a first insulating member containing oxygen and silicon.

17. The memory device of claim 1, wherein
upper surfaces of the memory pillars and upper surfaces of the second pillars are aligned.

18. The memory device of claim 1, further comprising
a plurality of second conductive layers provided apart from the first conductive layers in the second direction and arranged in the first direction, each of the second conductive layers having a portion provided to extend in a third direction crossing the first direction and the second direction, wherein
each of the memory pillars is coupled to one second conductive layer among the second conductive layers, and any conductive layers apart from the first conductive layers in the second direction are not coupled to the second pillars.

19. The memory device of claim 1, further comprising a third conductive layer and a fourth conductive layer provided between the substrate and the first conductive layers and arranged to face each other in the second direction, wherein
the substrate is provided with a control circuit electrically connected to the memory pillars via the third conductive layer and the fourth conductive layer, and
the third conductive layer and the fourth conductive layer have tapered shapes different from each other.

20. The memory device of claim 1, further comprising
a fifth conductive layer provided between the substrate and the first conductive layers and connected to one end of each of the memory pillars, wherein
the fifth conductive layer functions as a source line.
